(19) United States
(12) Patent Application Publication
(10) Pub. No.: US 2025/0301920 A1
(43) Pub. Date: Sep. 25, 2025

(54) QUANTUM DEVICES IN NANOSHEET TECHNOLOGY

(71) Applicant: International Business Machines Corporation, Armonk, NY (US)

(72) Inventors: Min Gyu Sung, Latham, NY (US); Matthias Mergenthaler, Zurich (CH); Andreas Fuhrer Janett, Zurich (CH); Julien Frougier, Albany, NY (US); Ruilong Xie, Niskayuna, NY (US); Chanro Park, Clifton Park, NY (US); Juntao Li, Cohoes, NY (US)

(21) Appl. No.: 18/613,507

(22) Filed: Mar. 22, 2024

(51) Int. Cl. H10N 60/10; B82Y 10/00

(52) U.S. Cl. CPC H10N 60/128; H10N 60/11; B82Y 10/00

(57) ABSTRACT

A method of operation that includes a nano quantum dot device. The nano quantum dot device that includes a nanosheet or nanowire. A first contact and a second contact connected to the nanosheet or nanowire. A plurality of gates located between the first contact and the second contact. At least a three-gate group is formed from the plurality of gates. The three-gate group have a set alignment order for the potential of each of the gates in the three-gate group and the alignment order consists of a first high potential gate, a low potential gate and a second high potential gate.

### BACKGROUND

The present invention generally relates to the field of quantum computers and semiconductor devices, and more particularly to the formation of quantum dots within nanosheets, where the quantum dots can host a spin, which can be utilized for quantum information processing.

Modulation of entangled quantum states forms the basis of quantum computation. Nanosheet is the lead device architecture in continuing CMOS scaling. Utilizing nanosheet technology for quantum devices and qubits is the next step in a continued development of semiconductor quantum devices for quantum computing applications.

### BRIEF SUMMARY

Additional aspects and/or advantages will be set forth in part in the description which follows and, in part, will be apparent from the description, or may be learned by practice of the invention.

A microelectronic structure that includes a nanosheet or nanowire. A first contact and a second contact connected to the nanosheet or nanowire. A plurality of gates located between the first contact and the second contact.

A microelectronic structure that includes a nanosheet or nanowire. A first contact and a second contact connected to the nanosheet or nanowire. A plurality of gates located between the first contact and the second contact. A center gate located directly on top of the nanosheet or nanowire.

A method of operation that includes a nano quantum dot device. The nano quantum dot device that includes a nanosheet or nanowire. A first contact and a second contact connected to the nanosheet or nanowire. A plurality of gates located between the first contact and the second contact. At least a three-gate group is formed from the plurality of gates. The three-gate group have a set alignment order for the potential of each of the gates in the three-gate group and the alignment order consists of a first high potential gate, a low potential gate and a second high potential gate.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a top-down view of a nanosheet quantum dot device, in accordance with the embodiment of the present invention.

FIG. 2 illustrates a cross section X1 of the nanosheet quantum dot device after formation of the initial layers, in accordance with the embodiment of the present invention.

FIG. 3 illustrates a cross section X1 of the nanosheet quantum dot device after an initial patterning stage, in accordance with the embodiment of the present invention.

FIG. 4 illustrates a cross section X1 of the nanosheet quantum dot device after formation of a shallow trench isolation layer, in accordance with the embodiment of the present invention.

FIG. 5 illustrates a cross section X1 of the nanosheet quantum dot device after formation of a plurality of dummy gates, in accordance with the embodiment of the present invention.

FIG. 6 illustrates a cross section X1 of the nanosheet quantum dot device after formation of a gate spacers, in accordance with the embodiment of the present invention.

FIG. 7 illustrates a cross section X1 of the nanosheet quantum dot device after formation of an interlayer dielectric layer, in accordance with the embodiment of the present invention.

FIG. 8 illustrates a cross section X1 of the nanosheet quantum dot device after the removal of the dummy gate, in accordance with the embodiment of the present invention.

FIG. 9 illustrates a cross section X1 of the nanosheet quantum dot device after formation of additional interlayer dielectric layer, in accordance with the embodiment of the present invention.

FIG. 10 illustrates a cross section X1 of the nanosheet quantum dot device after the removal of the gate spacers to form the gate trench, in accordance with the embodiment of the present invention.

FIG. 11 illustrates a cross section X1 of the nanosheet quantum dot device after extending the gate trench into the first layer, in accordance with the embodiment of the present invention.

FIG. 12 illustrates a cross section X1 of the nanosheet quantum dot device after the formation of a plurality of gates, in accordance with the embodiment of the present invention.

FIG. 13 illustrates a cross section X1 of the nanosheet quantum dot device after recessing of interlayer dielectric layer, in accordance with the embodiment of the present invention.

FIG. 14 illustrates a cross section X1 of the nanosheet quantum dot device after the removal of the first layer, in accordance with the embodiment of the present invention.

FIG. 15 illustrates a cross section X1 of the nanosheet quantum dot device after formation of additional interlayer dielectric layer, in accordance with the embodiment of the present invention.

FIG. 16 illustrates a cross section X1 of the nanosheet quantum dot device after formation of the source/drains, in accordance with the embodiment of the present invention.

FIG. 17 illustrates a cross section X2 of the nanosheet quantum dot device after the formation of the low potential gate contacts in accordance with the embodiment of the present invention.

FIG. 18 illustrates a cross section X3 of the nanosheet quantum dot device after formation of the high potential gate contacts, in accordance with the embodiment of the present invention.

FIG. 19 illustrates a cross section X1 of the nanosheet quantum dot device after formation of the source/drain contacts, in accordance with the embodiment of the present invention.

FIG. 20 illustrates a top-down view of a nanosheet quantum dot device, in accordance with the embodiment of the present invention.

FIG. 21 illustrates a cross section X1 of the nanosheet quantum dot device after formation of the initial layers, in accordance with the embodiment of the present invention.

FIG. 22 illustrates a cross section X1 of the nanosheet quantum dot device after an initial patterning stage and the formation of a shallow trench isolation layer, in accordance with the embodiment of the present invention.

FIG. 23 illustrates a cross section X1 of the nanosheet quantum dot device after formation of the dummy gate, hardmask and the initial patterning of these layers, in accordance with the embodiment of the present invention.

FIG. 24 illustrates a cross section X1 of the nanosheet quantum dot device after formation of first spacers, formation of source/drain trenches, and the formation of a second spacer, in accordance with the embodiment of the present invention.

FIG. 25 illustrates a cross section X1 of the nanosheet quantum dot device after formation of the source/drains, in accordance with the embodiment of the present invention.

FIG. 26 illustrates a cross section X1 of the nanosheet quantum dot device after formation of an interlayer dielectric layer, in accordance with the embodiment of the present invention.

FIG. 27 illustrates a cross section X1 of the nanosheet quantum dot device after formation of a plurality of gate trenches within the gate region, in accordance with the embodiment of the present invention.

FIG. 28 illustrates a cross section X1 of the nanosheet quantum dot device after formation of a plurality of gate trench extension within the first layer, in accordance with the embodiment of the present invention.

FIG. 29 illustrates a cross section X1 of the nanosheet quantum dot device after formation of a plurality of gates, in accordance with the embodiment of the present invention.

FIG. 30 illustrates a cross section X1 of the nanosheet quantum dot device after planarization process, in accordance with the embodiment of the present invention.

FIG. 31 illustrates a cross section X1 of the nanosheet quantum dot device after removal of the first spacer, the dummy gate, the second spacer, and any remaining material of the first layer, in accordance with the embodiment of the present invention.

FIG. 32 illustrates a cross section X1 of the nanosheet quantum dot device after formation of a fill layer, in accordance with the embodiment of the present invention.

FIG. 33 illustrates a cross section X1 of the nanosheet quantum dot device after increasing the height of the interlayer dielectric layer, the formation of the source/drain contacts, the low potential gate contacts, the height potential gate contacts and the formation of the quantum dots, in accordance with the embodiment of the present invention.

FIG. 34 illustrates a cross section X2 of the nanosheet quantum dot device after increasing the height of the interlayer dielectric layer, the formation of the source/drain contacts, the low potential gate contacts, the height potential gate contacts and the formation of the quantum dots, in accordance with the embodiment of the present invention.

FIG. 35 illustrates a cross section X3 of the nanosheet quantum dot device after increasing the height of the interlayer dielectric layer, the formation of the source/drain contacts, the low potential gate contacts, the height potential gate contacts and the formation of the quantum dots, in accordance with the embodiment of the present invention.

FIG. 36 illustrates a top-down view of a nanosheet quantum dot device, in accordance with the embodiment of the present invention.

FIG. 37 illustrates a cross section X of the nanosheet quantum dot device after an initial process of the initial layers, in accordance with the embodiment of the present invention.

FIG. 38 illustrates a cross section Y1 of the nanosheet quantum dot device after an initial process of the initial layers, in accordance with the embodiment of the present invention.

FIG. 39 illustrates a cross section X of the nanosheet quantum dot device after patterning the sacrificial layer, in accordance with the embodiment of the present invention.

FIG. 40 illustrates a cross section Y1 of the nanosheet quantum dot device after patterning the sacrificial layer, in accordance with the embodiment of the present invention.

FIG. 41 illustrates a cross section X of the nanosheet quantum dot device after formation and pattering of a second sacrificial layer and formation of the source/drains, in accordance with the embodiment of the present invention.

FIG. 42 illustrates a cross section Y1 of the nanosheet quantum dot device after formation and patterning of a second sacrificial layer and formation of the source/drains, in accordance with the embodiment of the present invention.

FIG. 43 illustrates a cross section X of the nanosheet quantum dot device after formation of the interlayer dielectric layer, removal of the second sacrificial layer, and formation of a gate layer, in accordance with the embodiment of the present invention.

FIG. 44 illustrates a cross section Y1 of the nanosheet quantum dot device after formation of the interlayer dielectric layer, removal of the second sacrificial layer, and formation of a gate layer, in accordance with the embodiment of the present invention.

FIG. 45 illustrates a cross section X of the nanosheet quantum dot device after the removal of the sacrificial layer, in accordance with the embodiment of the present invention.

FIG. 46 illustrates a cross section Y1 of the nanosheet quantum dot device after the removal of the sacrificial layer, in accordance with the embodiment of the present invention.

FIG. 47 illustrates a cross section X of the nanosheet quantum dot device after of a spacer and the formation of the center gate, in accordance with the embodiment of the present invention.

FIG. 48 illustrates a cross section Y1 of the nanosheet quantum dot device after of a spacer and the formation of the center gate, in accordance with the embodiment of the present invention.

FIG. 49 illustrates a cross section X of the nanosheet quantum dot device after formation of a gate cap and separating the gate layer into a plurality of gate columns, in accordance with the embodiment of the present invention.

FIG. 50 illustrates a cross section Y1 of the nanosheet quantum dot device after formation of a gate cap and separating the gate layer into a plurality of gate columns, in accordance with the embodiment of the present invention.

FIG. 51 illustrates a cross section Y2 of the nanosheet quantum dot device after formation of a gate cap and separating the gate layer into a plurality of gate columns, in accordance with the embodiment of the present invention.

FIG. 52 illustrates a cross section X of the nanosheet quantum dot device after removal of the first layer and formation of a second layer, in accordance with the embodiment of the present invention.

FIG. 53 illustrates a cross section Y1 of the nanosheet quantum dot device after removal of the first layer and formation of a second layer, in accordance with the embodiment of the present invention.

FIG. 54 illustrates a cross section Y2 of the nanosheet quantum dot device after removal of the first layer and formation of a second layer, in accordance with the embodiment of the present invention.

FIG. 55 illustrates a cross section X of the nanosheet quantum dot device after increasing the height of the second layer, and formation of source/drain contacts, high potential gate contacts, low potential gate contacts, and a center gate contact, in accordance with the embodiment of the present invention.

FIG. 56 illustrates a cross section Y1 of the nanosheet quantum dot device after increasing the height of the second layer, and formation of source/drain contacts, high potential gate contacts, low potential gate contacts, and a center gate contact, in accordance with the embodiment of the present invention.

FIG. 57 illustrates a cross section Y2 of the nanosheet quantum dot device after increasing the height of the second layer, and formation of source/drain contacts, high potential gate contacts, low potential gate contacts, and a center gate contact, in accordance with the embodiment of the present invention.

FIG. 58 illustrates a cross section X of the nanosheet quantum dot device after back-end-of-the-line (BEOL) layer and formation of quantum dots, in accordance with the embodiment of the present invention.

FIG. 59 illustrates a cross section Y1 of the nanosheet quantum dot device after back-end-of-the-line (BEOL) layer and formation of quantum dots, in accordance with the embodiment of the present invention.

FIG. 60 illustrates a cross section Y2 of the nanosheet quantum dot device after back-end-of-the-line (BEOL) layer and formation of quantum dots, in accordance with the embodiment of the present invention.

FIG. 61 illustrates a top-down view of a nanosheet quantum dot device, in accordance with the embodiment of the present invention.

FIG. 62 illustrates a cross section Y1 of the nanosheet quantum dot device after a nanosheet or nanowire is formed on a first layer, in accordance with the embodiment of the present invention.

FIG. 63 illustrates a cross section Y1 of the nanosheet quantum dot device after formation and patterning of a gate and hardmask, in accordance with the embodiment of the present invention.

FIG. 64 illustrates a cross section Y1 of the nanosheet quantum dot device after formation of gate spacers, in accordance with the embodiment of the present invention.

FIG. 65 illustrates a cross section Y1 of the nanosheet quantum dot device after formation of an interlayer dielectric layer and a lithography layer, in accordance with the embodiment of the present invention.

FIG. 66 illustrates a cross section Y2 of the nanosheet quantum dot device after formation of the interlayer dielectric layer and the lithography layer, in accordance with the embodiment of the present invention.

FIG. 67 illustrates a cross section Y2 of the nanosheet quantum dot device after removal of portions of the gate and hardmask, in accordance with the embodiment of the present invention.

FIG. 68 illustrates a cross section Y1 of the nanosheet quantum dot device after formation of additional interlayer dielectric layer and removal of the lithograph layer, in accordance with the embodiment of the present invention.

FIG. 69 illustrates a cross section Y2 of the nanosheet quantum dot device after formation of additional interlayer dielectric layer and removal of the lithograph layer, in accordance with the embodiment of the present invention.

FIG. 70 illustrates a cross section Y1 of the nanosheet quantum dot device after formation of a section A and section B of the second lithography layer, in accordance with the embodiment of the present invention.

FIG. 71 illustrates a cross section Y2 of the nanosheet quantum dot device after formation of a section A and section B of the second lithography layer, in accordance with the embodiment of the present invention.

FIG. 72 illustrates a cross section Y1 of the nanosheet quantum dot device after formation of a center gate trench, in accordance with the embodiment of the present invention.

FIG. 73 illustrates a cross section Y2 of the nanosheet quantum dot device after formation of a center gate trench, in accordance with the embodiment of the present invention.

FIG. 74 illustrates a cross section Y1 of the nanosheet quantum dot device after formation of a center gate, in accordance with the embodiment of the present invention.

FIG. 75 illustrates a cross section Y2 of the nanosheet quantum dot device after formation of a center gate, in accordance with the embodiment of the present invention.

FIG. 76 illustrates a cross section Y1 of the nanosheet quantum dot device after removal of excess material to expose a top surface of gates, in accordance with the embodiment of the present invention.

FIG. 77 illustrates a cross section Y2 of the nanosheet quantum dot device after removal of excess material to expose a top surface of gates, in accordance with the embodiment of the present invention.

FIG. 78 illustrates a cross section X of the nanosheet quantum dot device after formation of source/drain contacts, high and low potential gate contacts, formation of metal lines, and formation of quantum dots, in accordance with the embodiment of the present invention.

FIG. 79 illustrates a cross section Y1 of the nanosheet quantum dot device after formation of source/drain contacts, high and low potential gate contacts, formation of metal lines, and formation of quantum dots, in accordance with the embodiment of the present invention.

FIG. 80 illustrates a cross section Y2 of the nanosheet quantum dot device after formation of source/drain contacts, high and low potential gate contacts, formation of metal lines, and formation of quantum dots, in accordance with the embodiment of the present invention.

FIG. 81 illustrates a cross section Y3 of the nanosheet quantum dot device after formation of source/drain contacts, high and low potential gate contacts, formation of metal lines, and formation of quantum dots, in accordance with the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of +8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will be packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout. The first embodiment of the present invention is directed to the formation of quantum dots, that can host a spin, within nanosheet or nanowires utilizing a three-gate design. High potential and low potential gates are in an alternating order along the length of the nanosheet or nanowire. The alternating order of the gates allows for the formation of quantum dots within the nanosheet, where the quantum dot can host a spin. Furthermore, alternating the potential of the gates allows for better control of the quantum dots and the spin. With nanosheet based flow, three-dimensional quantum confinement can be effectively fabricated and adjusted by structural parameters, which is beneficial compared to the conventional FinFET base flow. The three-dimensional quantum confinement is defined by the channel height, the width of the gate along the channel, and the distance between the adjacent gates. Channel height is defined by nanosheet (for example, Si sheet, or another suitable material) deposition thickness. The width of the gate is defined by the spacer etch. The distance between the gates is defined by the etching process such that the distance between the gates can be less than or equal to 10 nm.

A single charge carrier in the quantum dot has a property that is called spin which can be utilized to encode quantum information in. There are multiple encoding strategies for utilizing the spin property for qubits, for example, a qubit encoded in the spin of a single quantum dot or utilizing the spin property of the charge carriers in up to three quantum dots.

The second embodiment of the present invention is similar to the first embodiment. The difference is the method utilized to form the gates. The first embodiment utilizes a spacer (i.e., a gate spacer) for developing the gate locations, while the second embodiment forms the gate by forming gate trenches in a dummy gate. The method used by the first embodiment allows for thinner gates and for a lower pitch than the method used in/by the second embodiment.

The third and the fourth embodiment of the present invention are directed towards confining two parallel linear arrays of quantum dots in a single nanosheet by means of a fourth gate electrode, aiding the confinement of the quantum dots and allowing to simultaneously or individually control all the spins along both linear arrays. The first gate is a low potential gate that wraps around a portion of the nanosheet or nanowire. The quantum dot is located on the nanosheet beneath the low potential gate. A second gate is located on a first side of the first gate and a third gate is located on second side of the first gate. The gates are lined up along the length of the nanosheet in an alternating order, for example, the second gate, the first gate, then the third gate. The second gate and the third gate are high potential gates. The fourth gate is located on top of the nanosheet or nanowire. The fourth gate extends parallel to and along the length of the nanosheet. The fourth gate direction extends perpendicular to the first, second, and third gate direction. The fourth gate or the center gate is a high potential gate. The second gate, third gate, and the fourth gate allows for the control/tuning of the quantum dot.

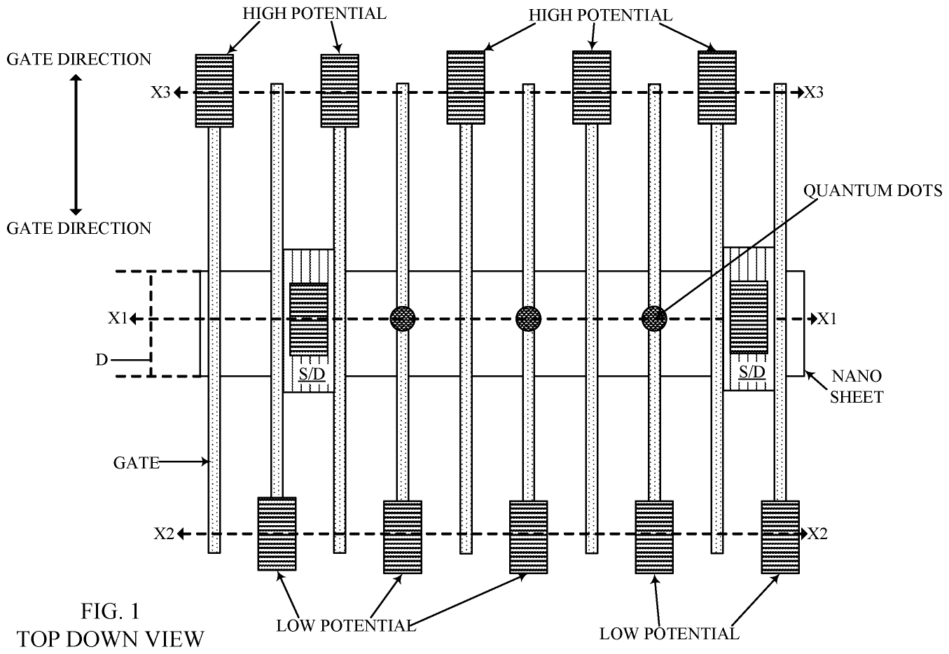

FIG. 1 illustrates a top-down view of the nanosheet quantum dot device, in accordance with the embodiment of the present invention. The cross-section X1 extends horizontally through nanosheet quantum dot device. Cross-section X1 is perpendicular to the gate direction. Cross-section X1 extends parallel to the length of the nanosheet. The cross-section X2 extends horizontally through nanosheet quantum dot device. Cross-section X2 is perpendicular to the gate direction. Cross-section X2 extends through the low potential gate contacts. The cross-section X3 extends horizontally through nanosheet quantum dot device. Cross-section X3 is perpendicular to the gate direction. Cross-section X3 extends through the high potential gate contacts.

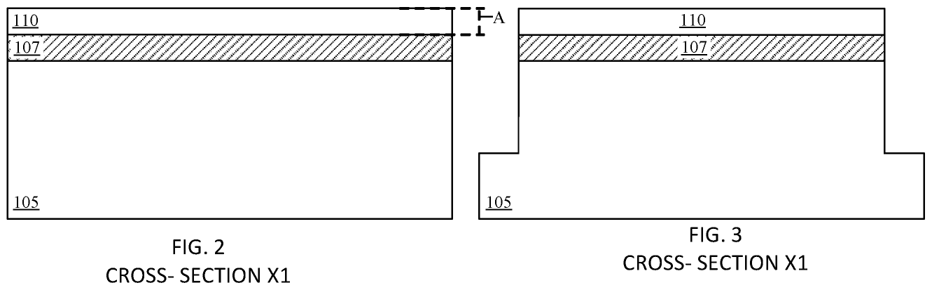

Referring now to FIGS. 2 and 3, a structure is shown during an intermediate step of a method of forming the initial layers and after an initial patterning stage. FIG. 2 illustrates substrate 105, a first layer 107 and a channel layer 110. Substrate 105 can be, for example, a material including, but not necessarily limited to, silicon (Si), silicon germanium (SiGe), Si: C (carbon doped silicon), carbon doped silicon germanium (SiGe: C), III-V, II-V compound semiconductor or another like semiconductor. In addition, multiple layers of the semiconductor materials can be used as the semiconductor material of the substrate 105. In some embodiments, substrate 105 includes both semiconductor materials and dielectric materials. The semiconductor substrate 105 may also comprise an organic semiconductor or a layered semiconductor such as, for example, Si/SiGe, a silicon-on-insulator or a SiGe-on-insulator. A portion or the entire semiconductor substrate 105 may also be comprised of an amorphous, polycrystalline, or monocrystalline. Semiconductor substrate 105 may be doped, undoped or contain doped regions and undoped regions therein. The first layer 107 can be comprised of a sacrificial material, for example, SiGe, where the concentration of Ge is in the range of about 10-50%. Channel layer 110 can be comprised of, for example, Si or another suitable material. Channel layer 110 can be a nanosheet, nanowire, or another suitable structure. Channel layer 110 has a thickness A

FIG. 3 illustrates the initial layers after a patterning step. Substrate 105, the first layer 107, and channel layer 110 are patterned/etched to form the initial shape of the channel layer 110. The patterning/etching stage forms the width D of the channel layer 110, as illustrated in FIG. 1. The patterning/etching stage further etches trenches in substrate 105.

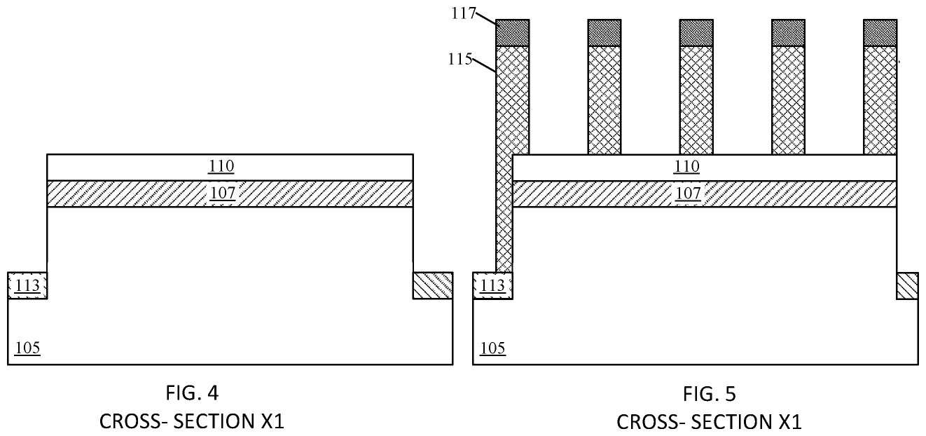

FIG. 4 illustrates the processing stage after the formation of a shallow trench isolation layer 113. A shallow trench isolation layer 113 is formed on top of the exposed surfaces of substrate 105. FIG. 5 illustrates the processing stage after formation of a plurality of dummy gates 115. A dummy gate layer 115 is formed on exposed surfaces of the shallow trench isolation layer 113 and on top of the channel layer 110. The first hardmask 117 is formed on top of the dummy gate layer 117. The first hardmask 117 and the dummy gate layer 115 are patterned/etched to separate the dummy gate layer 115 and the hardmask 117 into a plurality of columns.

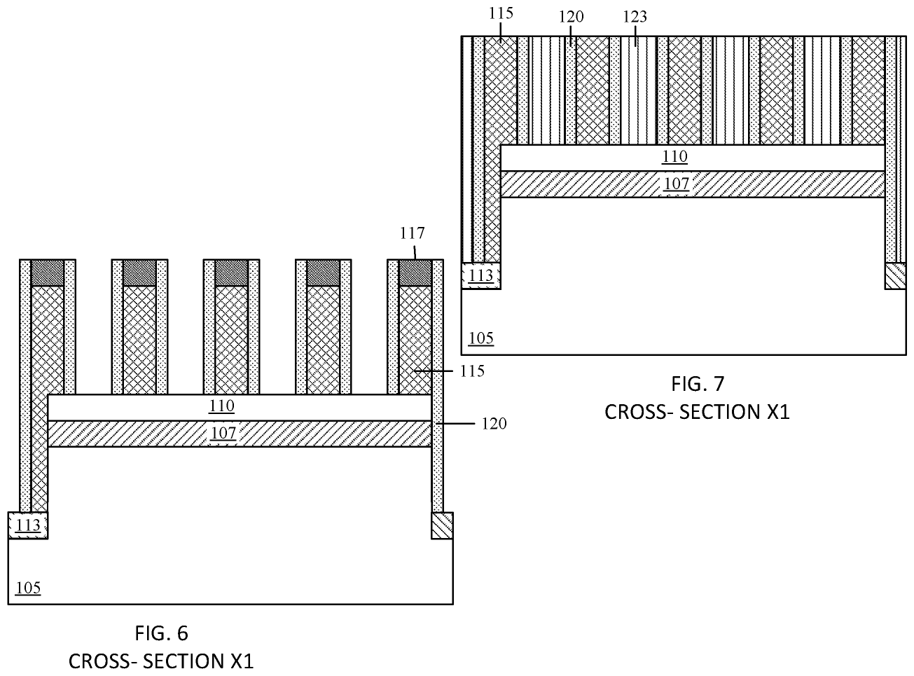

FIG. 6 illustrates the processing stage after the formation of the gate spacers 120. The gate spacers 120 are formed along the sidewalls of each of the plurality columns of the dummy gate 115 and the first hardmask 117. FIG. 7 illustrates the processing stage after the formation of the interlayer dielectric layer 123. The interlayer dielectric layer 123 is formed between the gate spacers 120 and on top of the first hardmask 117. Excess interlayer dielectric layer 123 material is removed and the first hardmask 117 is removed by, for example, chemical mechanical processing (CMP).

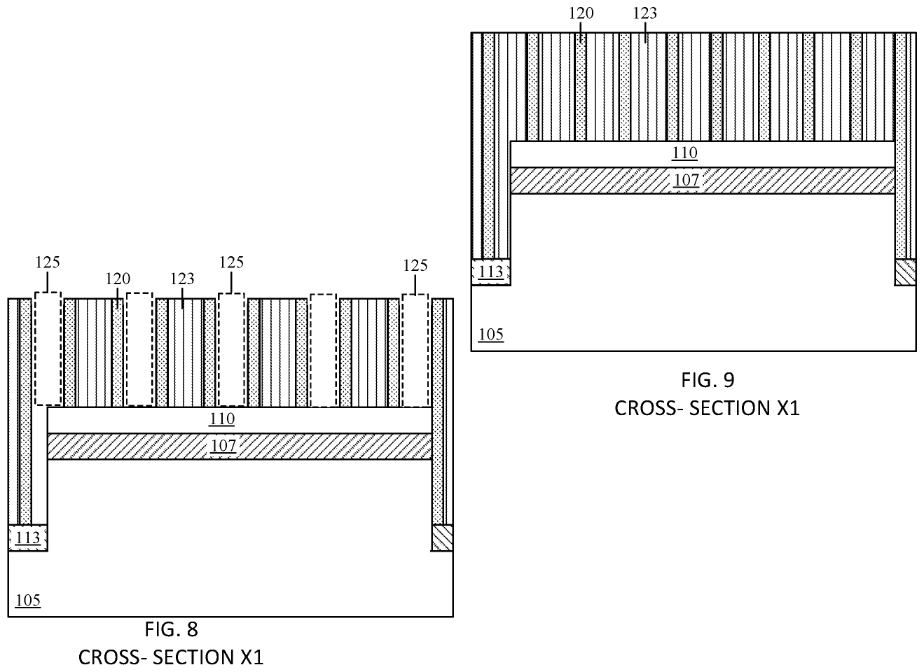

FIG. 8 illustrates the processing stage after the removal of the dummy gates 115. Dummy gates 115 are removed causing the formation of a plurality of trenches as emphasized by dashed box 125. Each of the plurality of trenches 125 are located between two vertical segments of the gate spacer 120. FIG. 9 illustrates the processing stage after additional interlayer dielectric material is added. Additional interlayer dielectric material is added to fill each of the trenches 135 with the interlayer dielectric layer 123. The interlayer dielectric layer 123 is located on both sides (as illustrated in the shown cross-section) of gate spacer 120.

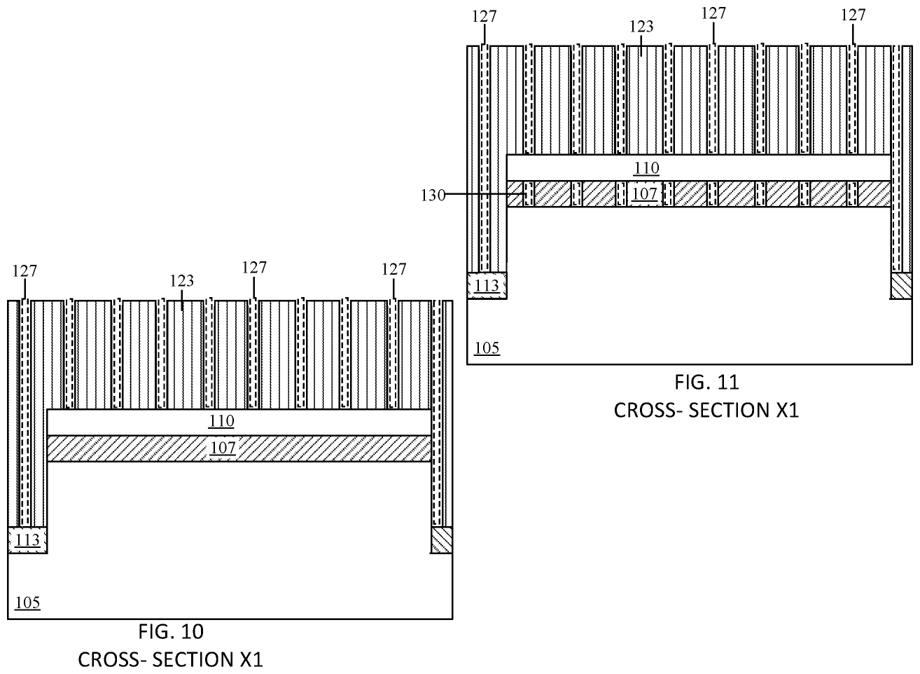

FIG. 10 illustrates the processing stage after the removal of the gate spacers 120 and the formation of the gate trenches 127. Gate spacers 120 are removed to form a plurality of gate trenches 127 within the interlayer dielectric layer 127. By utilizing the gate spacer 120 to form the gate trenches 127 instead of the dummy gate 115, the number gate trenches 127 increases. FIG. 11 illustrates the processing stage after the first layer 107 is trimmed to form a gate trenches extension 130. The first layer 107 is trimmed to form a plurality of gate trench extensions 130 within the first layer 107. The gate trenches extensions 130 form trenches beneath the channel layer 110.

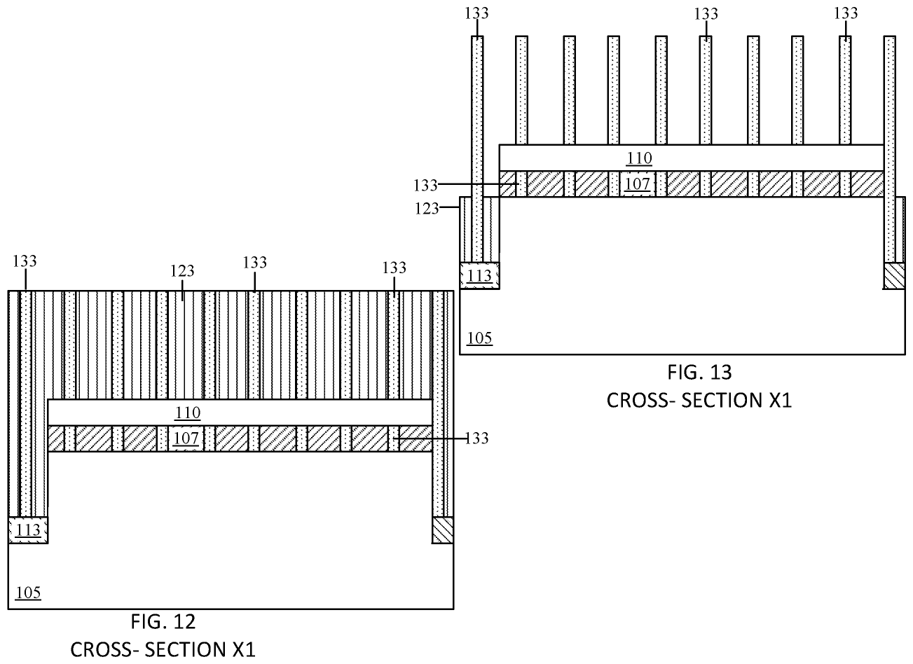

FIG. 12 illustrates the processing stage after the formation of a plurality of gates 133. The gate trenches 127 and the gate trench extensions 130 are filled in with gate material to form a plurality of gates 133. Gate 133 can be comprised of, for example, a gate dielectric liner, such as high-k dielectric like HfO₂, ZrO₂, HfLₐOₓ, etc., and work function layers, such as TiN, TiAlC, TiC, etc., and conductive metal fills, like W, and low K dielectrics like SiO₂, Al₂O₃. Each of the gates 133 that are located above and is in contact with the surface of the channel layer 110 also extends below and is in contact with a bottom surface of the channel layer 110. The gates 133 have a thickness B that directly corresponds to the thickness of the gate spacers 120. The gates 133 have a pitch C, e.g., the distance between adjacent gates 133, which is corresponds to the distance between two adjacent gate spacers 120. As illustrated in FIGS. 12 and 13, gates 133 can have a portion of gate 133 that extends beneath the channel layer 110, meaning that the gates 133 wrap around the channel layer 110. FIG. 13 illustrates the processing stage after recessing of the interlayer dielectric layer 123. The height of the interlayer dielectric layer 123 is reduced to expose the first layer 107.

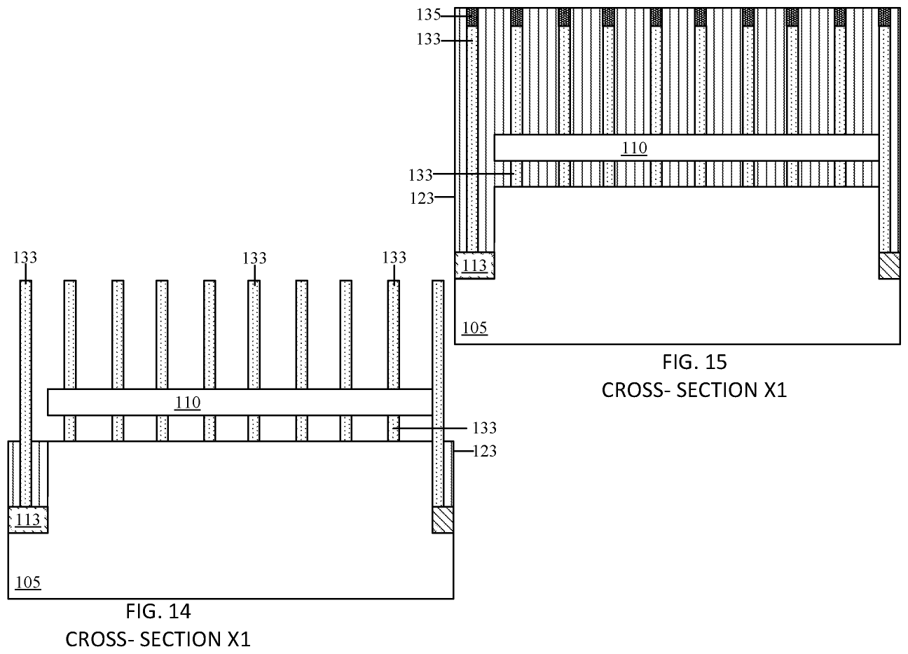

FIG. 14 illustrates the processing stage after the removal of the first layer 107. The first layer 107 is removed to separate the channel layer 110 from the substrate 105. FIG. 15 illustrates the processing stage after adding additional interlayer dielectric layer material. The height of the interlayer dielectric layer 123 is increased by adding more dielectric material, such that the interlayer dielectric layer 123 extends higher than the gates 133. Trenches (not shown) are formed in the interlayer dielectric layer 123 to expose the top of each of the gates 133, respectively. Gate caps 135 are formed by filling the trenches with suitable material, for example, SiN.

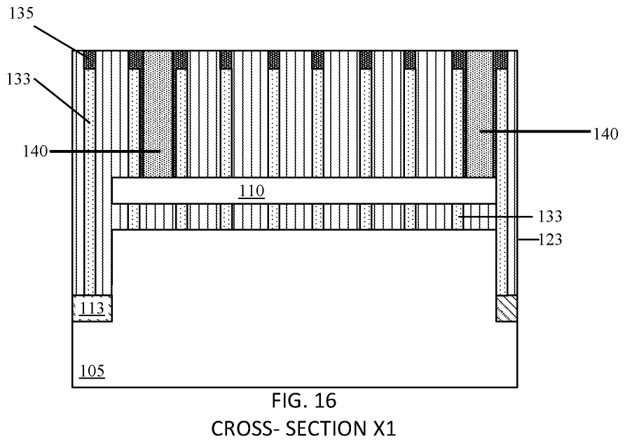

FIG. 16 illustrates the processing stage after the formation of the source/drains 140. Trenches (not shown) are formed in the interlayer dielectric layer 123 for the formation of the source/drains 140. Each trench is located between two different gates 133 and exposes the sidewalls of the gates 133 and exposes a top surface of the channel layer 110. Additional gate cap 135 material is added to form a liner along the vertical side surfaces of the exposed gates 133 to prevent the source/drain 140 from shorting with the gate 133. The source/drains 140 are epitaxially grown from the exposed top surface of the channel layer 110. The source/drains 140 can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (TI) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

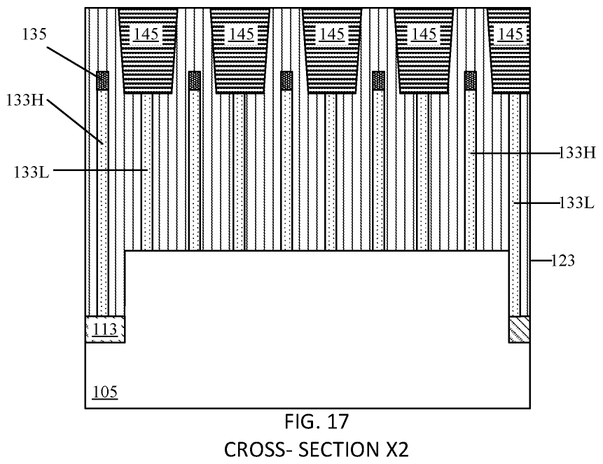

FIG. 17 illustrates the processing stage after the formation of the low potential gate contacts 145. The height of the interlayer dielectric layer 123 is increased by adding more dielectric material, such that the interlayer dielectric layer 123 extends over the gate caps 135. Trenches (not shown) are formed in the interlayer dielectric layer 123 to expose alternating gates 133. The exposed gates 133 will now be referred to as the low potential gates 133L. The trench is filled with a conductive material to form the low potential gate contact 145. A high potential gate 133H is located between each of the low potential gates 133L, such that, the high potential gates 133H and the low potential gates 133L are arranged in an alternating array. The use of the terms of high potential gate 133H and low potential gate 133L are being used for understanding reasons only. One of ordinary skill in the art would realize that these terms refer to electrodes or contacts that have the same structure as each other.

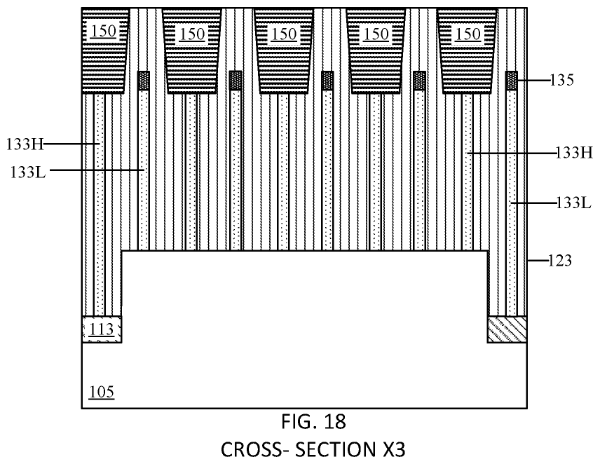

FIG. 18 illustrates the processing stage after the formation of the high potential gate contacts 150. Trenches (not shown) are formed in the interlayer dielectric layer 123 to expose alternating gates 133. The exposed gates 133 will now be referred to as the high potential gates 133H. The trench is filled with a conductive material to form the high potential gate contact 150. A high potential gate 133H is located between each of the low potential gates 133L, such that, the high potential gates 133H and the low potential gates 133L are arranged in an alternating array.

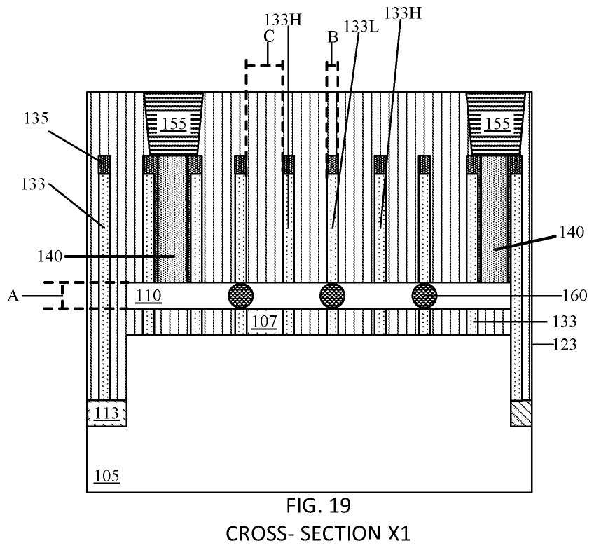

FIG. 19 illustrates the processing stage after the formation of the source/drain contacts 155. Trenches (not shown) are formed in the interlayer dielectric layer 123 to expose a top surface of the source/drains 140. Source/drain contacts 155 are formed by filling the trenches in with a conductive material. A plurality of quantum dots 160 are formed along the channel layer 110. The quantum dots 160 are located along channel layer 110 in potential wells created by the low and high potential gates 133L, 133H. The quantum dots 160 are located under the low potential gates 133L. The quantum dots 160 can host spins which can be utilized for storing and manipulating quantum information.

Quantum dots 160 are formed in a channel layer 110 by means of applying voltages to gate electrodes (high and low potential gates 133H, 133L) on top of the semiconductor, isolated by a dielectric (interlayer dielectric layer 123). The voltages accumulate a small section in the channel layer 110, basically the quantum dot 160 is an isolated puddle of a single or a couple of charge carriers (positive or negative). To achieve this the present invention utilizes a three dimensional confinement (high potential gate 133H, low potential gate 133L, high potential gate 133H). In the present invention, the direction of confinement is given by the nanosheet (channel layer 110), additionally a three gate system is needed plus at least one reservoir for charge carriers. The middle gate (e.g., the low potential gate 133L) defines the depth of the potential well and with the gates (e.g., the high potential gates 133H) on the side can tune the coupling of the quantum dot 160 either to a neighboring/adjacent quantum dot 160 (or potential well) or the rate at which charge carriers can be loaded into your quantum dot 160.

The high potential gates 133H located adjacent to the low potential gates 133L allow for controlling/tuning of the quantum dots 160/spins. The order of high potential gate 133H, low potential gate 133L, and a high potential gate 133H, as illustrated in FIG. 1, is a three-gate formation on the channel layer 110 for containing/controlling/tuning the quantum dot 160 and spin. Furthermore, by having a high potential gate 133H located on opposite sides of a low potential gate 133L (i.e., the low potential gate 133L is sandwiched between two adjacent high potential gates 133H) increases the confinement of the quantum dots 160. A potential well (or low point) forms under the low potential gates 133L and the high points of the potential well (i.e. the upper raising walls/trend) is formed by the high potential gates 133H. The quantum dot 160 is confined to the low point of the potential well, and by controlling the potential of the high potential gate 133H allows for the controlling/tuning of the potential well and the quantum dot 160 as well as the interaction between two spins. The width B of the high potential gate 133H and the width of the low potential gate 133L also affect the confinement of the quantum dots 160. By reducing the width B causes an increase or decrease (based on how close adjacent gates are) in the confinement of the quantum dots 160, because it allows for the pitch (i.e., distance C) to be reduced, allowing for the gates (133L, 133H) to be closer together. This leads to the potential well to have steeper high potential walls/trends because of the distance C between the high and low potential gates 133L, 133H. The gate pitch C affects the size/parameters/attributes of the potential well which directly affects the confinement/tuning of the quantum dots 160.

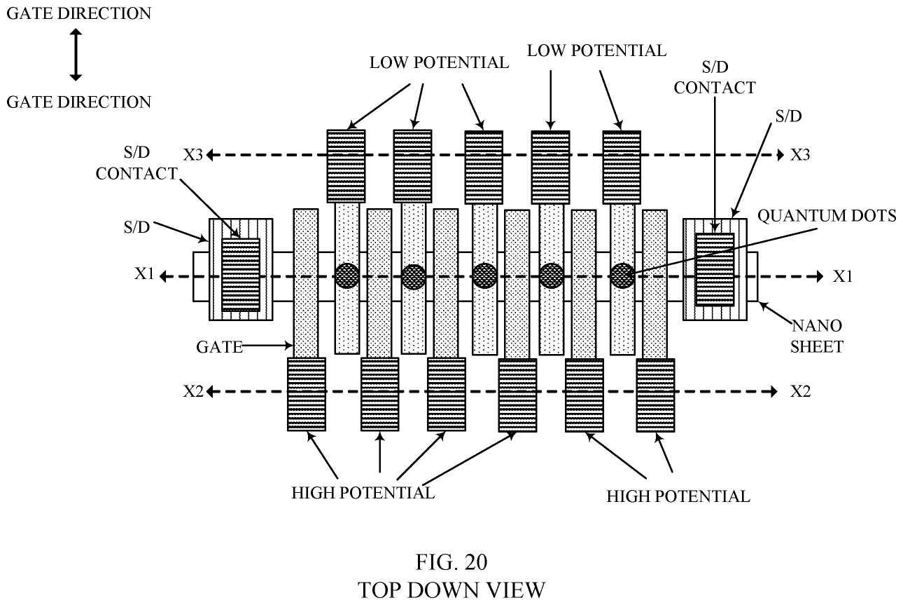

FIG. 20 illustrates a top-down view of the nanosheet quantum device, in accordance with the embodiment of the present invention. The cross-section X1 extends horizontally through nanosheet quantum dot device. Cross-section X1 is perpendicular to the gate direction. Cross-section X1 extends parallel to the length of the nanosheet. The cross-section X2 extends horizontally through nanosheet quantum dot device. Cross-section X2 is perpendicular to the gate direction. Cross-section X2 extends through the high potential gate contacts. The cross-section X3 extends horizontally through nanosheet quantum dot device. Cross-section X3 is perpendicular to the gate direction. Cross-section X3 extends through the low potential gate contacts and the source/drain contacts.

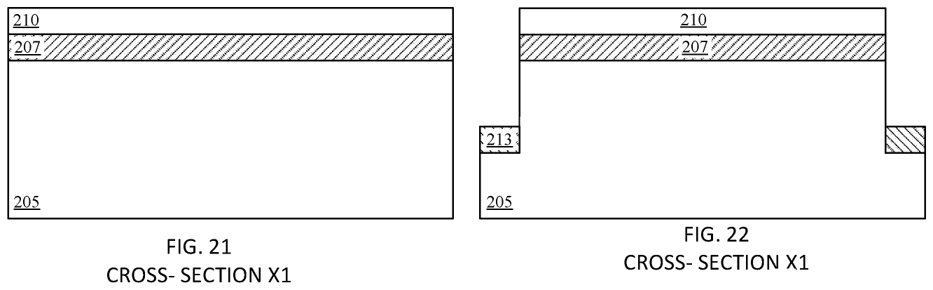

Referring now to FIGS. 21 and 22, a structure is shown during an intermediate step of a method of forming the initial layers and formation of the shallow trench isolation layer 213. FIG. 21 illustrates substrate 205, a first layer 207 and a channel layer 210. Substrate 205 can be, for example, a material including, but not necessarily limited to, silicon (Si), silicon germanium (SiGe), Si: C (carbon doped silicon), carbon doped silicon germanium (SiGe: C), III-V, II-V compound semiconductor or another like semiconductor. In addition, multiple layers of semiconductor materials can be used as the semiconductor material of the substrate 205. In some embodiments, substrate 205 includes both semiconductor materials and dielectric materials. The semiconductor substrate 205 may also comprise an organic semiconductor or a layered semiconductor such as, for example, Si/SiGe, a silicon-on-insulator or a SiGe-on-insulator. A portion or the entire semiconductor substrate 205 may also be comprised of an amorphous, polycrystalline, or monocrystalline. Semiconductor substrate 205 may be doped, undoped or contain doped regions and undoped regions therein. The first layer 207 can be comprised of a sacrificial material, for example, SiGe, where the concentration of Ge is in the range of about 10-50%. Channel layer 210 can be comprised of, for example, Si or another suitable material. Channel layer 210 can be a nanosheet, nanowire, or another suitable structure.

FIG. 22 illustrates the initial layers after a patterning step and the formation of the shallow trench isolation layer 213. Substrate 205, the first layer 207, and channel layer 210 are patterned/etched to form the initial shape of the nanosheet channel layer 210. A shallow trench isolation layer 213 is formed on top of the exposed surfaces of substrate 205.

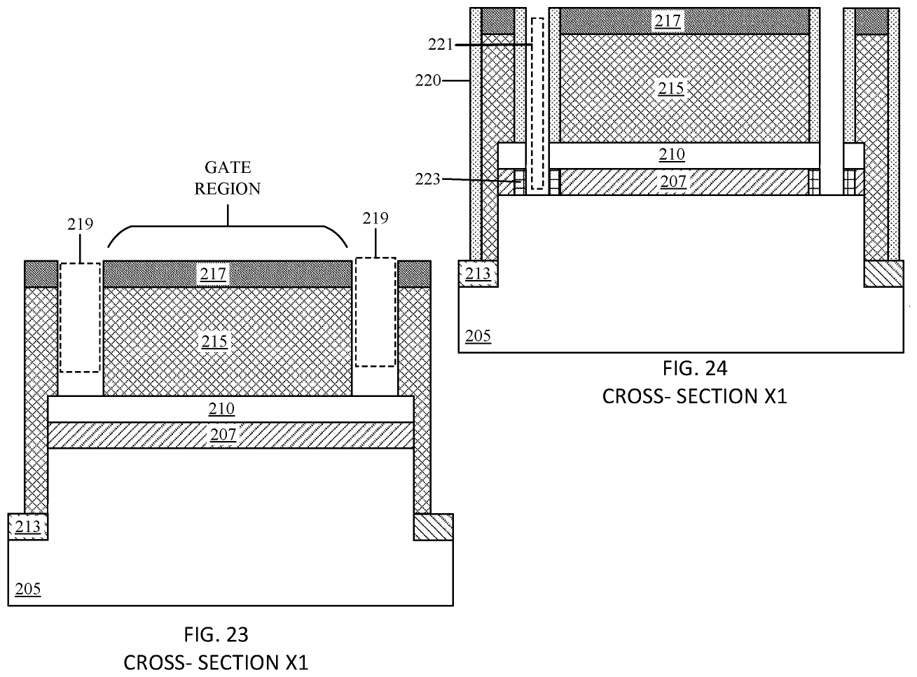

FIG. 23 illustrates the processing stage after the formation of the dummy gate 215 and hardmask 217. The dummy gate 215 is formed on top of channel layer 210 and the shallow trench isolation layer 213. The dummy gate 215 and the hardmask 217 are patterned to form a plurality of source/drain trenches 219. The source/drain trenches 219 expose a top surface of channel layer 210. A large section of the dummy gate 215 and the hardmask 217 remain on top of channel layer 210 between source/drain trenches 219. This area/region is the gate region, e.g., where the gates will be formed.

FIG. 24 illustrates the processing stage after the formation of a first spacer 220, extending the source/drain trench 221, and formation of a second spacer 223. The first spacer 220 is formed along the vertical sidewalls of the dummy gate 215 and the hardmask 217. The source/drain trench 219 is extended through the channel layer 210 and the first layer 207 to form the extended source/drain trenches 221. The first layer 207 is recessed around the extend source/drain trenches 221. A second spacer 223 is formed in the space created by the recessing of the first layer 207.

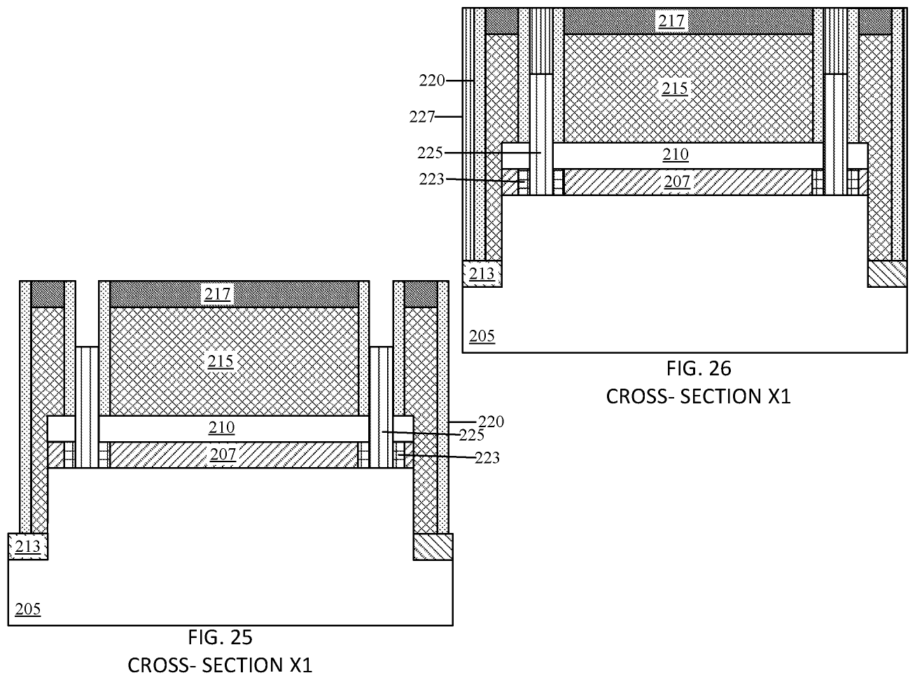

FIG. 25 illustrates the processing stage after the formation of the source/drains 225. The source/drains 225 are epitaxially grown from the exposed surfaces of channel layer 210. The source/drains 210 can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques. The source/drains 225 are in contact with a substrate 205, the second spacer 223, the channel layer 210, and the first spacer 220.

FIG. 26 illustrates the processing stage after the formation of the interlayer dielectric layer 227. The interlayer dielectric layer 227 is formed on top of the source/drains 225 and around the nanosheet quantum dot device.

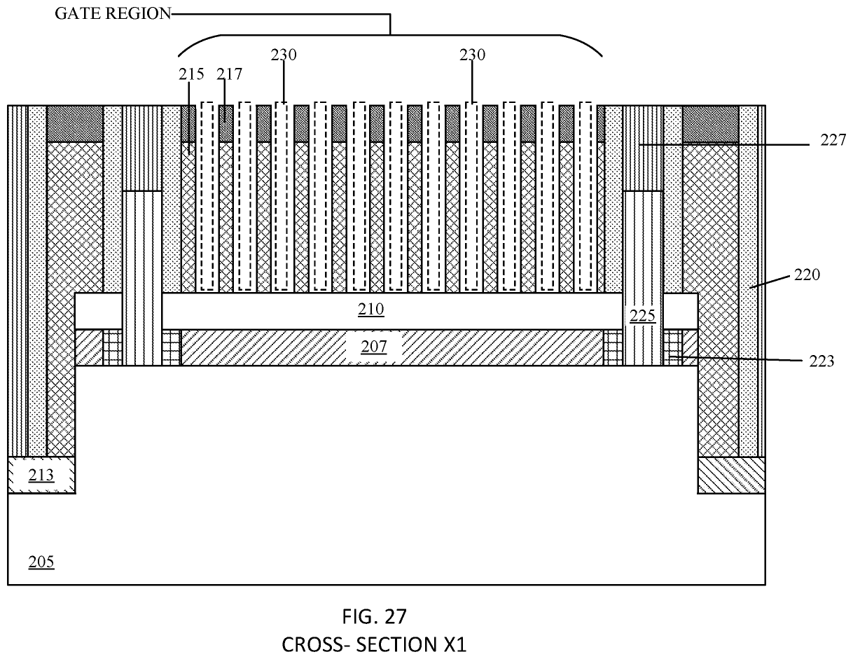

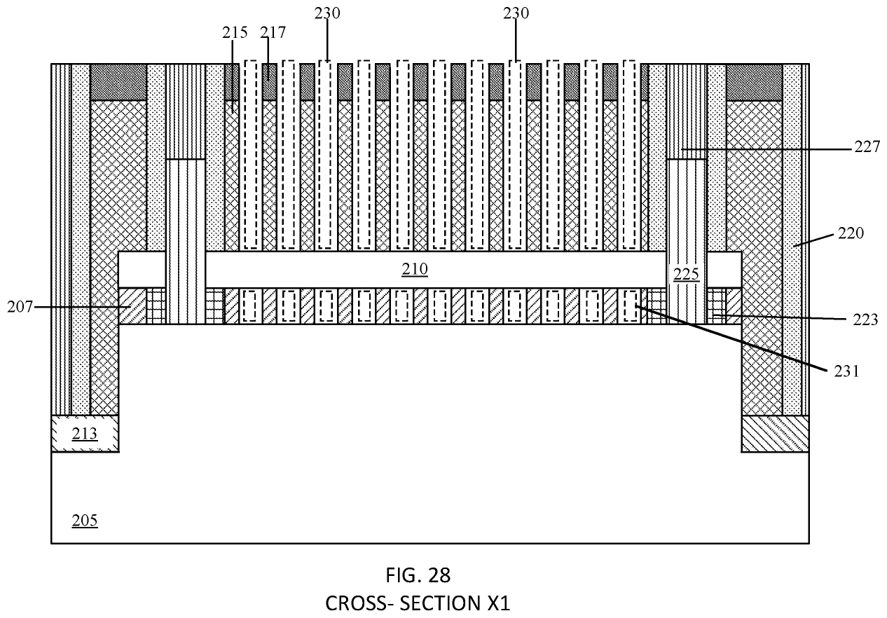

FIG. 27 illustrates the processing stage after formation of a plurality of gate trenches 230 within the gate region. A plurality of gate trenches 230 are formed in the gate region. Each of the gate trenches 230 extends down to and exposes a top surface of the channel layer 210. FIG. 28 illustrates the processing stage after formation of a plurality of gate trench extensions 231 within the first layer 207. The first layer 207 is trimmed to form a plurality of gate trench extensions 231 beneath the channel layer 210.

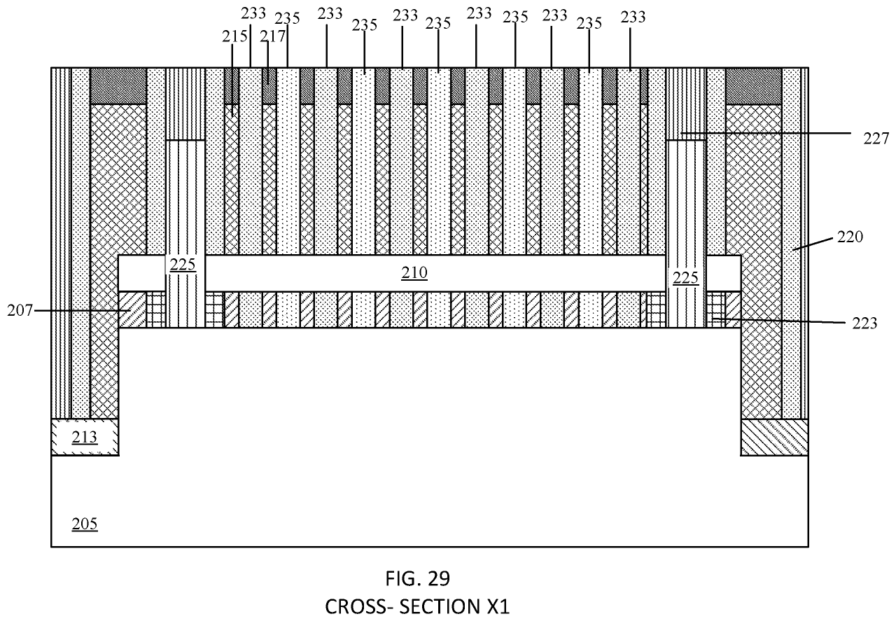

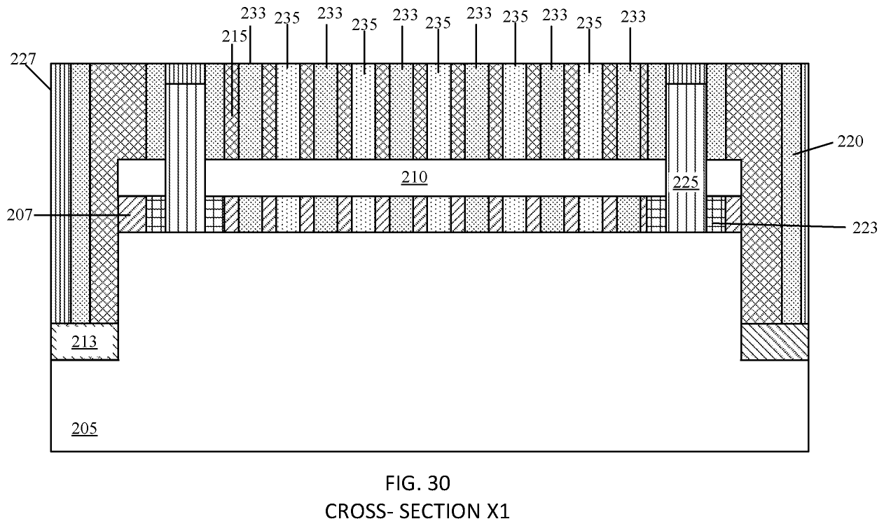

FIG. 29 illustrates the processing stage after formation of a plurality of gates 233, 235. The plurality of gate trenches 230 and the plurality of gate trench extensions 231 are filled with a conductive metal to form a plurality of gates 233, 235. Gate 233, 235 can be comprised of, for example, a gate dielectric liner, such as high-k dielectric like HfO₂, ZrO₂, HfLₐOₓ, etc., and work function layers, such as TiN, TiAlC, TiC, etc., and conductive metal fills, like W, and low K dielectrics like SiO₂, Al₂O₃. The first group of gates 233 will be referred as the high potential gates 233 and a second group of gates 235 will be referred as the low potential gates 235. As illustrated in FIG. 29, high potential gates 233 and low potential gates 235 can have a portion that extends beneath the channel layer 210, meaning that the high potential gates 233 and low potential gates 235 wrap around the channel layer 210. FIG. 30 illustrates the processing stage after planarization process. The nanosheet quantum dot device is planarized for example by, a chemical mechanical planarization process (CMP) to remove excess material (e.g., hardmask 217, interlayer dielectric layer 227). The planarization process forms a uniform/flat surface across the plurality of gates 233, 235 and the source/drains 225.

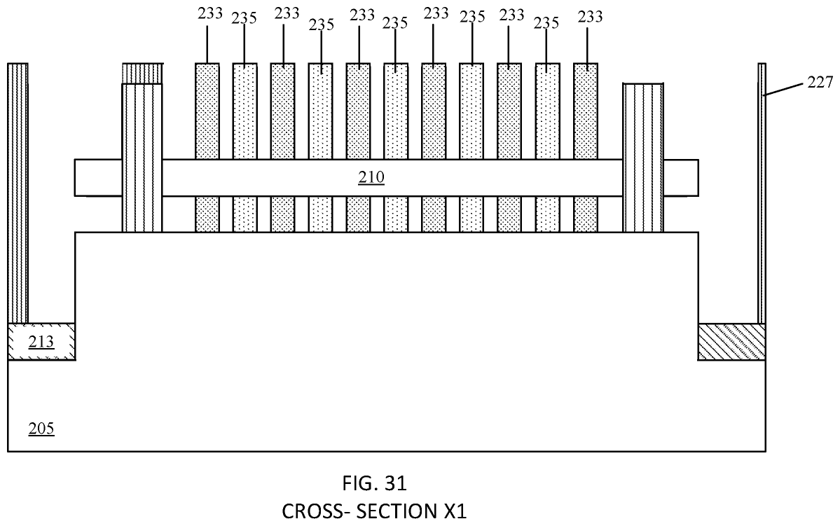

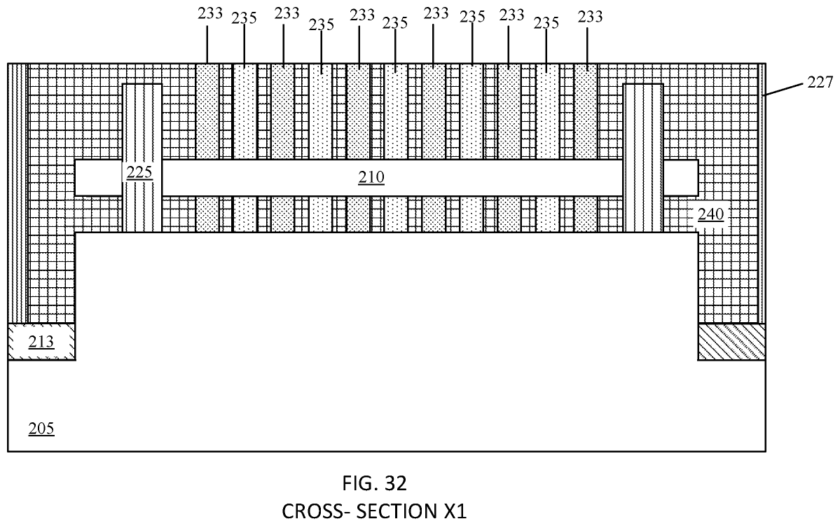

FIG. 31 illustrates the processing stage after removal of the first spacer 220, the dummy gate 215, the second spacer 223, and any remaining material of the first layer 207. The first spacer 220, the dummy gate 215, the second spacer 223, and the first layer 207 are removed. The removal of these layers exposes the plurality of gates 233, 235, the channel layer 210, and the source/drains 225. FIG. 32 illustrates the processing stage after formation of a fill layer 240. The empty space created by the removal of the first spacer 220, the dummy gate 215, the second spacer 223, and the first layer 207 is filled with a material to form the fill layer 240. Fill layer 240 is comprised of material the act as an isolation/insulation layer that prevent the plurality of gates 233, 235, and the source/drains 225 from shorting each other. Fill layer 240 can be comprised of, for example, an oxide layer such as SiO₂.

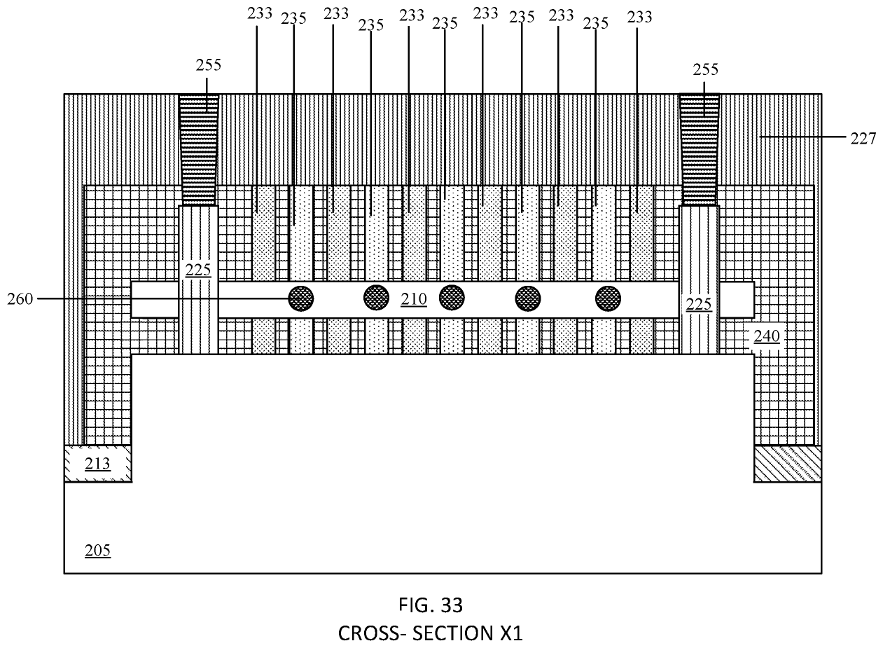

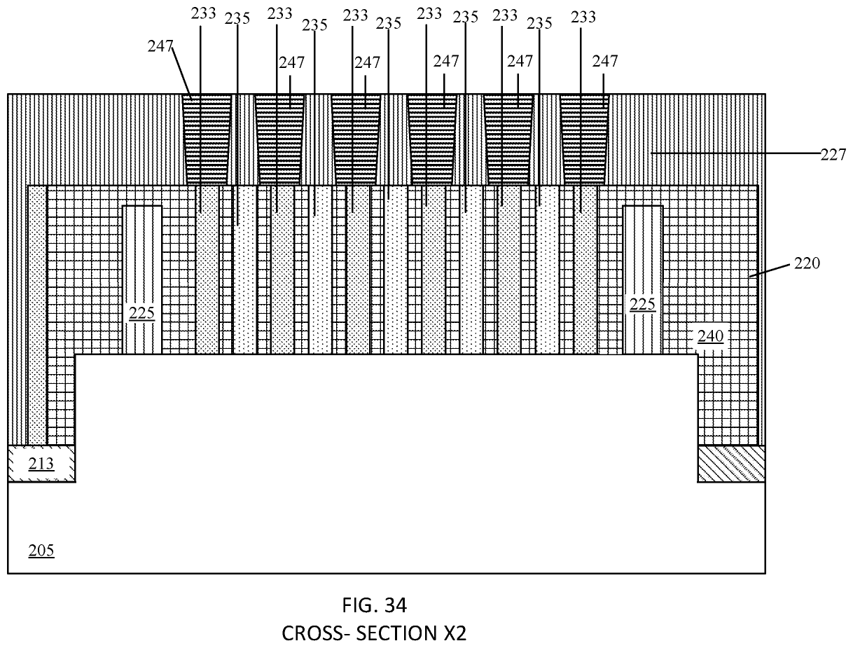

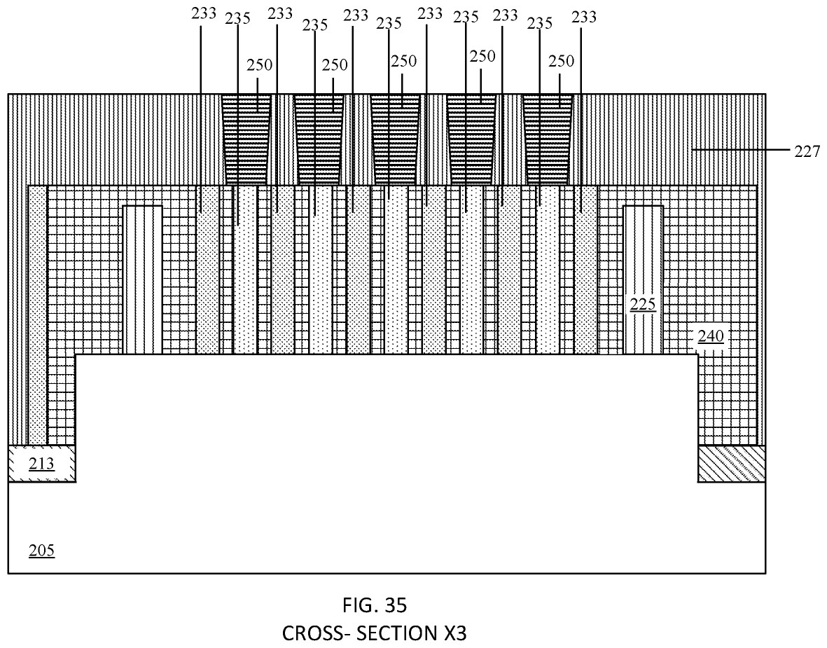

FIGS. 33, 34, and 35 illustrate the processing stage after increasing the height of the interlayer dielectric layer 227, the formation of the source/drain contacts 255 (as illustrated in FIG. 35), the low potential gate contacts 250 (as illustrated in FIG. 35), the height potential gate contacts 247 (as illustrated in FIG. 34) and the formation of the quantum dots 260. The height of the interlayer dielectric layer 227 is increased by adding more dielectric material, such that the interlayer dielectric layer 227 extends over the plurality of gates 233, 235 and the source/drains 225. Trenches (not shown) are formed in the interlayer dielectric layer 227 to expose a top surface of the source/drains 225. The trenches are filled in with a conductive material to form the source/drain contacts 255. A plurality of quantum dots 260 are formed along and within the channel layer 210 where each can host an individual spin. The quantum dots 260 are located along the channel layer 210 in potential wells created by the low and high potential gates 233, 235. The adjacent high potential gates 233 located adjacent to the low potential gates 235 allow for controlling/tuning of the quantum dots 260 or spins. Furthermore, by having a high potential gate 260 located on opposite sides of a low potential gate 235 (i.e., the low potential gate 235 is sandwiched between two adjacent high potential gates 233) increases the confinement of the quantum dots 260. A potential well (or low point) forms under the low potential gates 235 and the high points of the potential well (i.e. the upper raising walls/trend) is formed by the high potential gates 233. The order of high potential gate 233, low potential gate 235, and a high potential gate 233, as illustrated in FIG. 20, is a three-gate formation on the channel layer 210 for containing/controlling/tuning the quantum dot 260. The quantum dot 260 is confined to the low point of the potential well, and by controlling the potential of the high potential gate 233 allows for the controlling/tuning of the potential well and the quantum dot 260. The width of the high potential gate 233 and the width of the low potential gate 235 also affect the confinement of the quantum dots 260. The width of the high potential gates 233 and the width of the low potential gates 235 affect gate pitch (i.e., distance between adjacent gates). The gate pitch determines how close the adjacent gates (i.e., low potential gate 235 and the high potential gate 233) are to each other.

Quantum dots 260 are formed in a channel layer 210 by means of applying voltages to gate electrodes (high and low potential gates 233, 235) on top of the semiconductor, isolated by a dielectric (fill layer 240). The voltages accumulate a small section in the channel layer 210, basically the quantum dot 260 is an isolated puddle of a single or a couple of charge carriers (positive or negative). To achieve this the present invention utilizes a three dimensional confinement (high potential gate 233, low potential gate 235, high potential gate 233). In the present invention, the direction of confinement is given by the nanosheet (channel layer 210), additionally a three gate system is needed plus at least one reservoir for charge carriers. The middle gate (e.g., the low potential gate 235) defines the depth of the potential well and with the gates (e.g., the high potential gates 233) on the side can tune the coupling of the quantum dot 160 either to a neighboring/adjacent quantum dot 260 (or potential well) or the rate at which charge carriers can be loaded into your quantum dot 260. The gate pitch affects the size/parameters/attributes of the potential well which directly affects the confinement/tuning of the quantum dots 260.

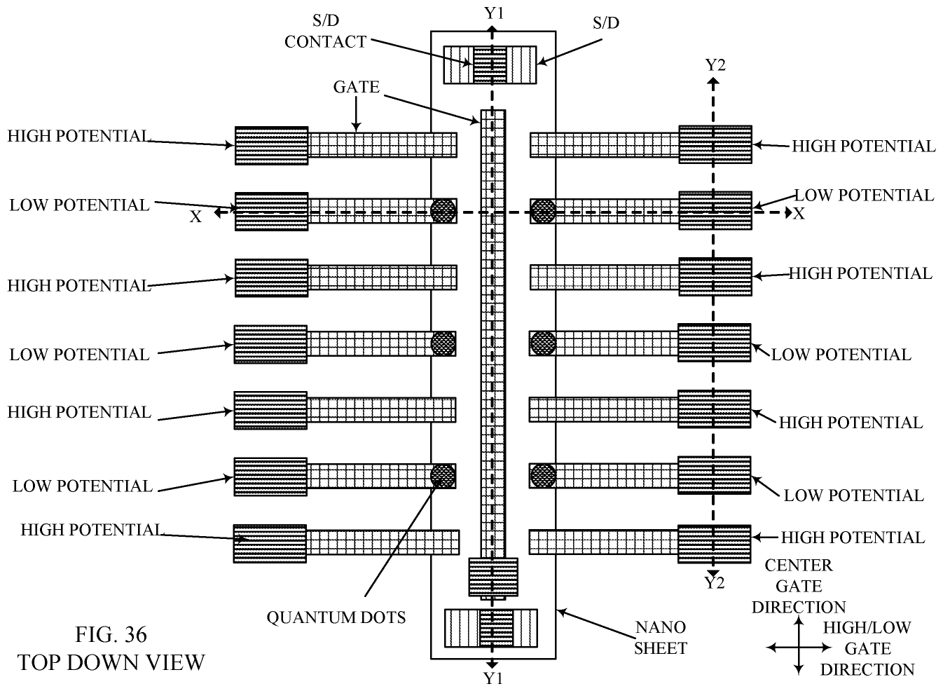

FIG. 36 illustrates a top-down view of the nanosheet quantum dot device, in accordance with the embodiment of the present invention. The cross-section X extends horizontally through nanosheet quantum dot device. Cross-section X is perpendicular to the length of the nanosheet direction and parallel to the gates that extend from the sides of the nanosheet. The cross-section Y1 extends through the center of the nanosheet quantum dot device. Cross-section Y1 extends parallel along the length of the nanosheet and parallel to the center gate. Cross-section Y2 extends parallel along the length of the nanosheet and perpendicular to the side gates. Cross-section Y2 extends through the low potential gate contacts and high potential gate contacts.

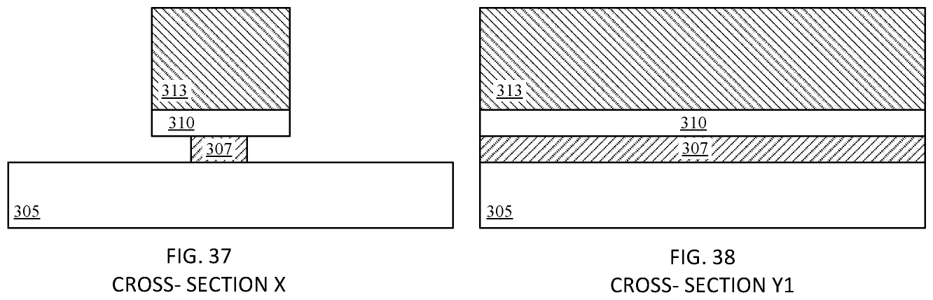

Referring now to FIGS. 37 and 38, a structure is shown during an intermediate step of a method of patterning the layers. FIG. 37 illustrates substrate 305, a first layer 307, a channel layer 310, and a sacrificial layer 313. Substrate 305 can be, for example, a material including, but not necessarily limited to, silicon (Si), silicon germanium (SiGe), Si: C (carbon doped silicon), carbon doped silicon germanium (SiGe: C), III-V, II-V compound semiconductor or another like semiconductor. In addition, multiple layers of semiconductor materials can be used as the semiconductor material of the substrate 305. In some embodiments, substrate 305 includes both semiconductor materials and dielectric materials. The semiconductor substrate 305 may also comprise an organic semiconductor or a layered semiconductor such as, for example, Si/SiGe, a silicon-on-insulator or a SiGe-on-insulator. A portion or the entire semiconductor substrate 305 may also be comprised of an amorphous, polycrystalline, or monocrystalline material. Semiconductor substrate 305 may be doped, undoped or contain doped regions and undoped regions therein. The first layer 307 can be comprised of a sacrificial material, for example, SiGe, where the concentration of Ge is in the range of about 10-50%. Channel layer 310 can be comprised of, for example, Si or another suitable material. Channel layer 310 can be a nanosheet, nanowire, or another suitable structure. The sacrificial layer 313 can be comprised of, for example, SiN. FIG. 37 illustrates that the channel layer 310 extends past/overhangs the first layer 307.

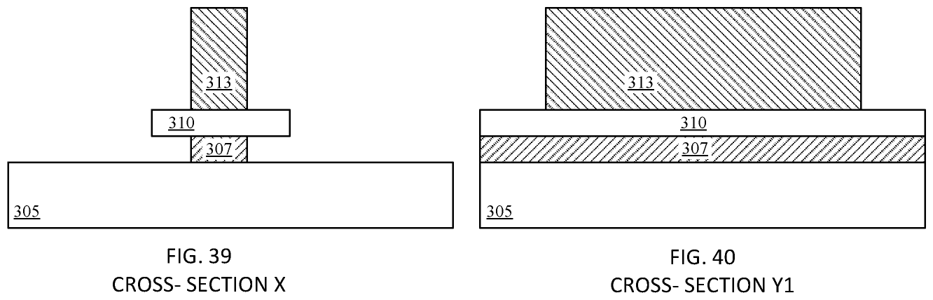

FIGS. 39 and 40 illustrate the processing stage after patterning the sacrificial layer 313. The sacrificial layer 313 is patterned to reduce the width of the layer, as illustrated in FIG. 39, and reduce the length of the sacrificial layer 313, as illustrated in FIG. 40. The sacrificial layer 313 is essential for the formation of a center gate that extends along the length of the channel layer 310.

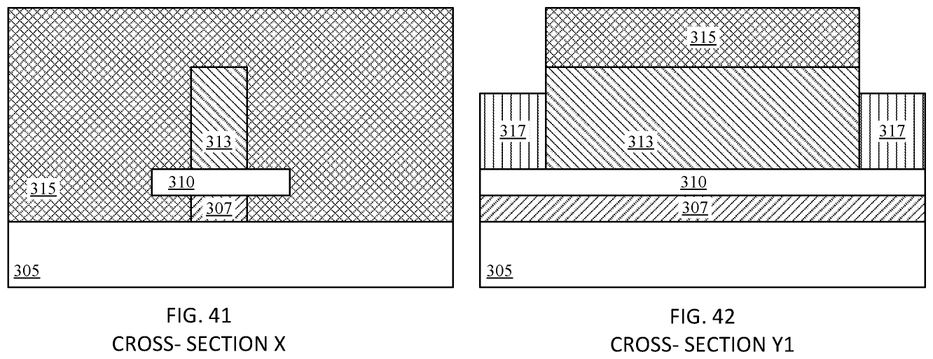

FIGS. 41 and 42 illustrate the processing stage after formation and patterning of a second sacrificial layer 315 and formation of the source/drains 317. A second sacrificial layer 315 is formed on top of the exposed surfaces and patterning to expose the source/drain region located at the towards the ends of the channel layer 310. The source/drains 317 are epitaxially grown from the exposed top surface of channel layer 310. The source/drains 317 can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

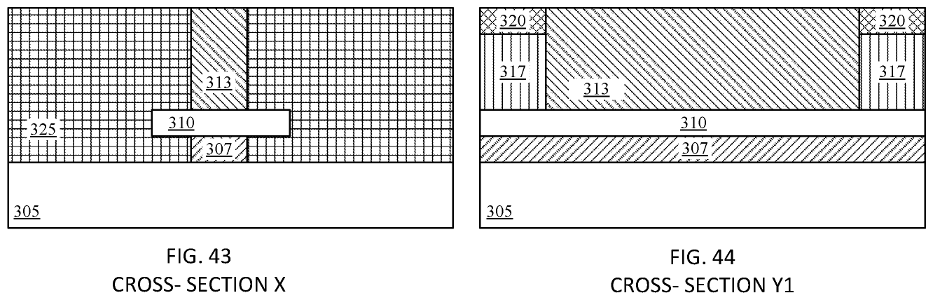

FIGS. 43 and 44 illustrate the processing stage after formation of the interlayer dielectric layer 320, removal of the second sacrificial layer 315, and formation of a gate layer 325. An interlayer dielectric layer 320 is formed on top of the source/drains 317. The second sacrificial layer 315 is removed. Gate layer 325 is formed on each side of channel layer 310, as illustrated in FIG. 43. Gate layer 325 extends on top of and below a portion of the channel layer 310. Sacrificial layer 313 and the first layer 307 prevent the gate layers 325 from enclosing the channel layer 310. Gate layer 325 can be comprised of, for example, a gate dielectric liner, such as high-k dielectric like HfO₂, ZrO₂, HfLₐOₓ, etc., and work function layers, such as TiN, TiAlC, TiC, etc., and conductive metal fills, like W, and low K dielectrics like SiO₂, Al₂O₃, or include non work-function layers such as doped polySi etc. As illustrated in FIG. 43 the gate layer 325 extends on top of and below the channel layer 310.

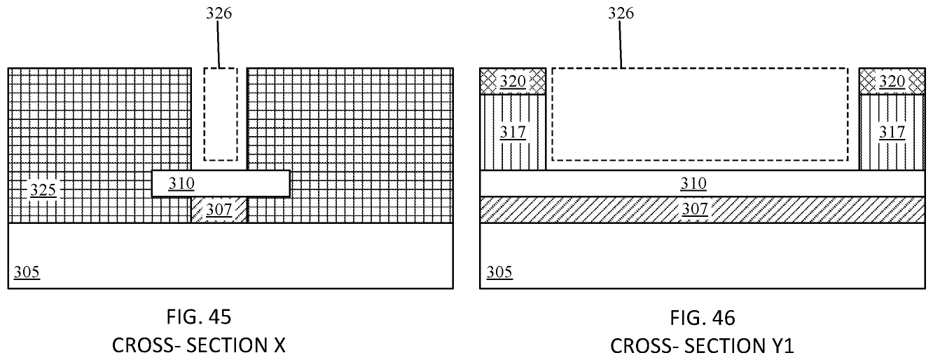

FIGS. 45 and 46 illustrate the processing stage after the removal of the sacrificial layer 313. Sacrificial layer 313 is removed to create a trench 326 that is located along the center of the channel layer 310. Gate layers 325 comprise the side boundaries of trench 326 and the source/drains 317 form the end boundaries of trench 326.

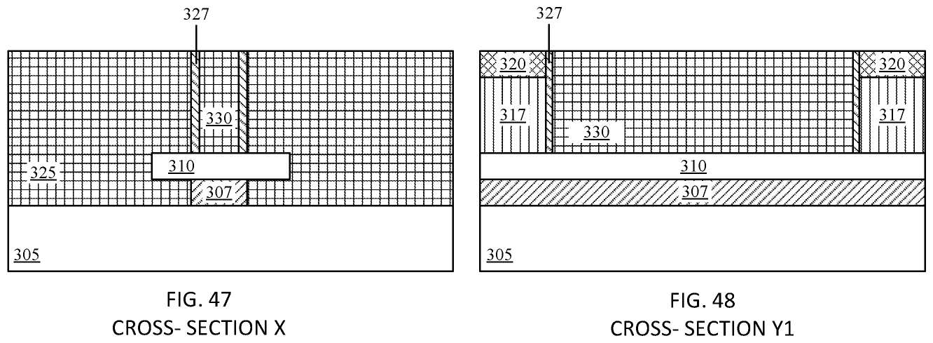

FIGS. 47 and 48 illustrate the processing stage after of a spacer 327 and the formation of the center gate 330. Spacer 327 is formed in trench 326, such that the spacer 327 lines the boundaries of trench 326. Spacer 327 is formed along the exposed sidewall of the gate layers 327, as illustrated in FIG. 47, and along exposed sidewall of the source/drain 327 and the interlayer dielectric layer 320. The remaining space within trench 326 is filled with gate material to form the center gate 330. Center gate 330 can be comprised of, for example, a gate dielectric liner, such as high-k dielectric like HfO₂, ZrO₂, HfLₐOₓ, etc., and work function layers, such as TiN, TiAlC, TiC, etc., and conductive metal fills, like W, and low K dielectrics like SiO₂, Al₂O₃, or include non-work-function layers such as doped polySi etc.

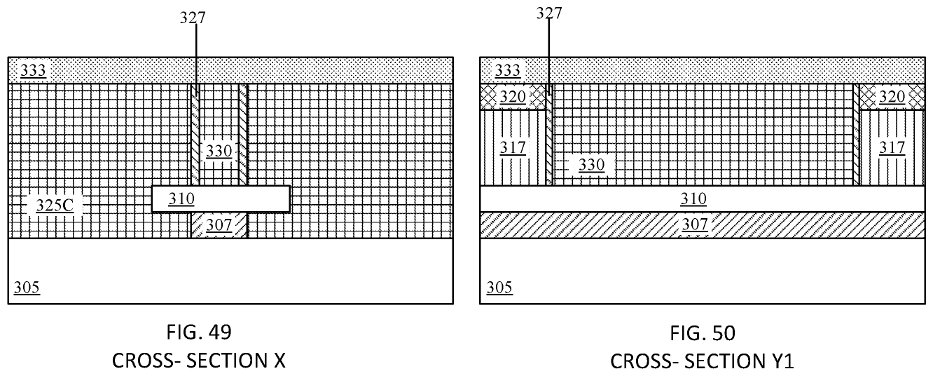

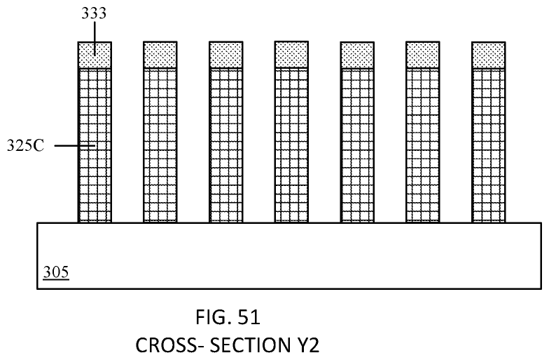

FIGS. 49, 50 and 51 illustrate the processing stage after formation of a gate cap 333 and separating the gate layer 325 into a plurality of gate columns 325C. Gate cap 333, or a hardmask, is formed on top of gate layer 325, the center gate 330, spacer 327, interlayer dielectric layer 320. The gate cap 333 can be comprised of, for example, SiN. The gate cap 333 and the gate layer 325 are etched/patterned to separate the gate layer 325 into a plurality of separate gates or gate columns 325C, as illustrated in FIG. 51. Each of the gate columns 325C extends on top of and below the channel layer 310, such that each of the gate columns 325C wraps around the edge of the channel layer 310.

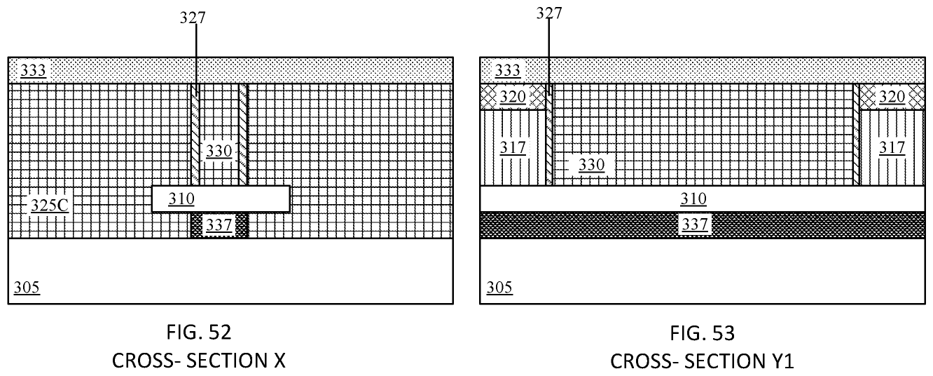

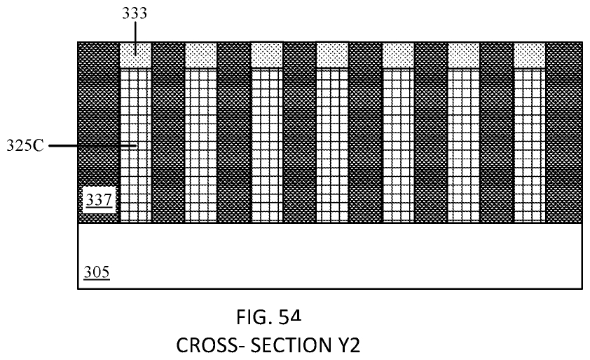

FIGS. 52, 53 and 54 illustrate the processing stage after removal of the first layer 307 and formation of a second layer 337. The first layer 307 is removed to create an empty space (not shown) beneath channel layer 310. This empty space beneath channel layer 310 and the space between the gate columns 325C is filled with a second layer 337. The second layer 337 is comprised of a suitable material that will isolate/electrically separate each of the plurality of gate columns 325C from each other and to isolate/electrically separate the channel layer 310 from the substrate 305. The second layer 337 can be comprised of, for example, an oxide such as SiO₂ or another suitable oxide.

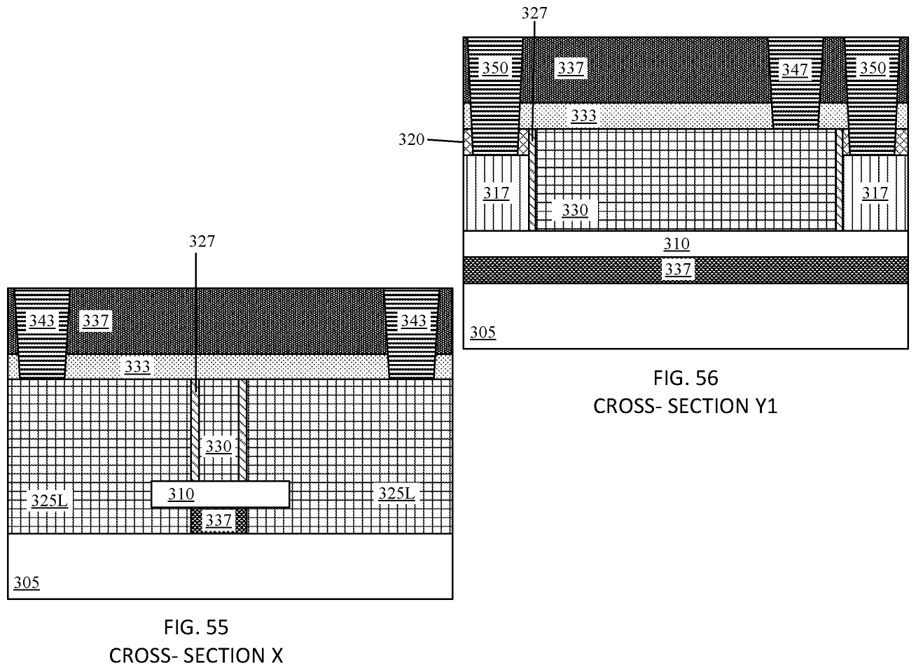

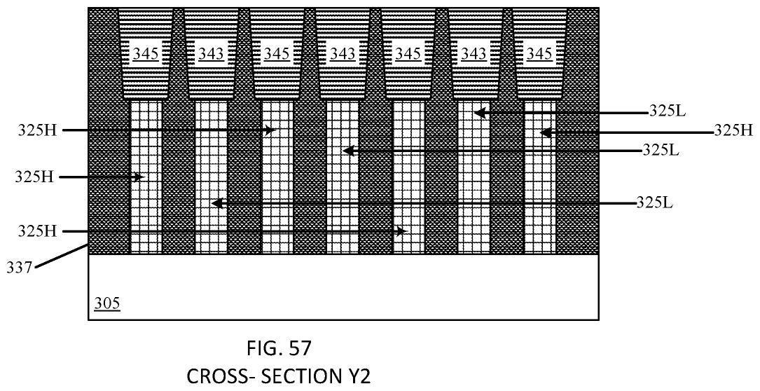

FIGS. 55, 56 and 57 illustrate the processing stage after increasing the height of the second layer 337, and formation of source/drain contacts 350, high potential gate contacts 345, low potential gate contacts 343, and a center gate contact 347. The height of the second layer 337 is increased by adding more material, such that the second layer 337 extends over the plurality of gate cap 333. Trenches (not shown) are formed in the second layer 337, gate cap 333, and the interlayer dielectric layer 320 to expose a top surface of the source/drains 317. The trenches are filled in with a conductive material to form the source/drain contacts 350. A trench (not shown) is formed in the second layer 337 and the gate cap 333 to expose a top surface of the center gate 330. The trench is filled with conductive material to form the center gate contact 347. A plurality of trenches (not shown) is formed in the second layer 337, where each of the trenches exposes a top surface of the one of the gate columns 325C. These trenches are filled with conductive materials to form high potential gate contacts 345 and low potential gate contacts 343. The gate columns 325C connected to the high potential gate contacts 345 will now be referred to as the high potential gates 325H. The gate columns 325C connected to the low potential gate contacts 343 will now be referred to as the low potential gates 325L. The high potential gates 325H and the low potential gates 325L are arranged in alternating fashion as illustrated in FIG. 57.

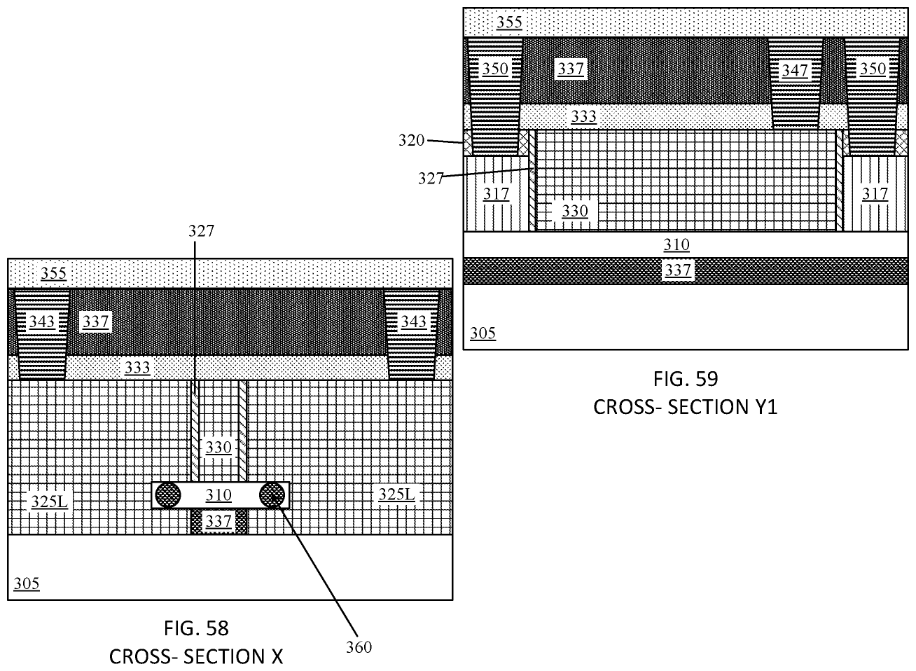

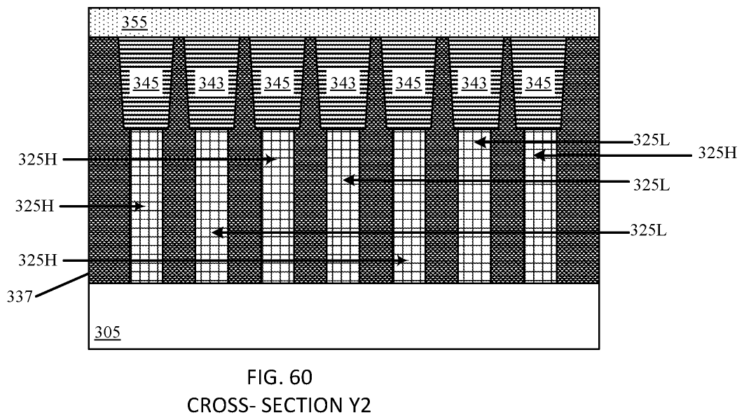

FIGS. 58, 59 and 60 illustrate the processing stage after back-end-of-the-line (BEOL) layer 355 and formation of quantum dots 360. A back-end-of-the-line (BEOL) layer 355 is formed on top of the source/drain contacts 350, the center gate contact 347, the high potential gate contacts 345, the low potential gate contacts 343, and the second layer 337.

A plurality of quantum dots 360 are formed along the channel layer 310. The quantum dots 360 can host spins which can be utilized for storing and manipulating quantum information. The quantum dots 360 are located along channel layer 310 in potential wells created by the low and high potential gates 325L, 325H. The adjacent high potential gates 325H allow for controlling/tuning of the quantum dots 360. Furthermore, by having a high potential gate 325H located on opposite sides of a low potential gate 325L (i.e., the low potential gate 325L is sandwiched between two adjacent high potential gates 325H) increases the confinement of the quantum dot 360 and allows control of the quantum dot 360 parameters. A potential well (or low point) forms under the low potential gates 325L and the high point of the potential well (i.e. the upper raising walls/trend) is formed by the high potential gates 325H. The quantum dots 360 are confined to the low point of the potential well, and by controlling the potential of the high potential gate 325H allows for the controlling/tuning of the potential well and the quantum dot 360. In addition, tuning of the low potential gate 325L tunes the confinement and the potential well of the quantum dot 360. The width of the high potential gate 325H and the width of the low potential gate 325L also affect the confinement of the quantum dots 360. The center gate 330 is another high potential gate. The center gate 330 runs parallel to the channel layer 310 and runs perpendicular to the high potential gates 325H and the low potential gates 325L. The center gate 330 provides another control/turning option for the potential well. As seen in FIGS. 36, and 58 cross-section X illustrates a horizontal cut through the channel layer 310, where the horizontal cut extends through a low potential gate 325L located on each side of the channel layer 310. The center gate 330 provides a high point potential well that will be formed between the two aligned low potential gates 325L.

Quantum dots 360 are formed in a channel layer 310 by means of applying voltages to gate electrodes (high and low potential gates 325H, 325L) on top of the semiconductor, isolated by a dielectric (second layer 337). The voltages accumulate a small section in channel layer 310, basically the quantum dot 360 is an isolated puddle of a single or a couple of charge carriers (positive or negative). To achieve this the present invention utilizes a four-gate confinement (high potential gate 325, low potential gate 325L, high potential gate 325H) and the addition of the center gate 330. In the present invention, the direction of confinement is given by the nanosheet (channel layer 310), additionally a four-gate system is needed plus at least one reservoir for charge carriers. The middle gate (e.g., the low potential gate 325L) defines the depth of the potential well and with the gates (e.g., the high potential gates 325H) on the side can tune the coupling of the quantum dot 360 either to a neighboring/adjacent quantum dot 360 (or potential well) or the rate at which charge carriers can be loaded into your quantum dot 360. The center gate 330 allows for the tuning of the potential well, control the interaction between the two rails (the row of gates on each side of the center gate 330) and allows for magnetic driving of spin rotations of the spin qubits 360, i.e. single spin qubit control.

Therefore, the center gate 330 provides the opportunity to separate the two sides of the device and provides an additional means of tuning the quantum dots 360 located in the potential wells. The center gate 330 has the functionality of controlling the spins with a magnetic field arising from passing a current through that central gate 330. FIG. 59 illustrates the presence of only one center gate contact 347, this meant for example purposes only. One or more gates 347 can be connected to the center gate 330, such that a center gate 347 could be located at each end of the center gate 330. The multiple center gate contacts 347 improves the operation of the center gate in controlling/tuning the quantum dot 360 in the potential well.

FIGS. 36, and 58-60 illustrate a four-gate formation (i.e., a low potential gate 325L sandwiched between two adjacent high potential gates 325H, and the center gate 330) for quantum dot 360 confinement. The first gate is a low potential gate 325L that wraps around a portion of the nanosheet or nanowire (i.e., channel layer 310). The quantum dot 360 is located within the nanosheet (i.e., channel layer 310) beneath the low potential gate 325L. A second gate is located on the first side of the first gate and a third gate is located on the second side of the first gate. The gates are lined up along the length of the nanosheet (i.e., channel layer 310, see, for example, FIG. 36) in an alternating order, for example, the second gate (i.e., high potential gate 325H), the first gate (i.e., the low potential gate 325L), then the third gate (i.e., another high potential gate 325H). The second gate and the third gate are high potential gates 325H. The fourth gate (i.e., the center gate 330) is located on top of the nanosheet or nanowire (i.e., channel layer 310). The fourth gate (i.e., the center gate 330) extends parallel to and along the length of the nanosheet (i.e., channel layer 310). The fourth gate direction extends perpendicular to the first, second, and third gate direction, as illustrated in FIG. 36. The fourth gate or the center gate 330 is a high potential gate. The second gate, third gate, and the fourth gate allow for the control/tuning of the quantum dot 360.

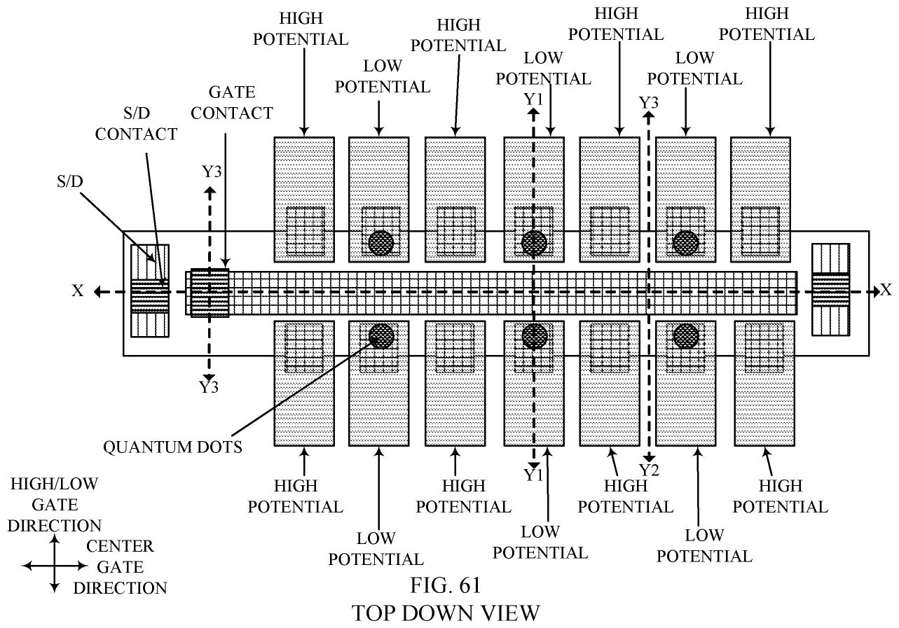

FIG. 61 illustrates a top-down view of the nanosheet quantum dot device, in accordance with the embodiment of the present invention. Cross-section X extends horizontally through nanosheet quantum dot device. Cross-section X is parallel to the length of the nanosheet/nanowire direction and perpendicular to the gates that extend from the sides of the nanosheet. Cross-section Y1 extends through a low potential gate of the nanosheet quantum dot device. Cross-section Y1 extends perpendicular to the length of the nanosheet/nanowire. Cross-section Y2 extends through the area between two adjacent gates, where cross-section Y2 is parallel to the gates and perpendicular to the length of the nanosheet/nanowire.

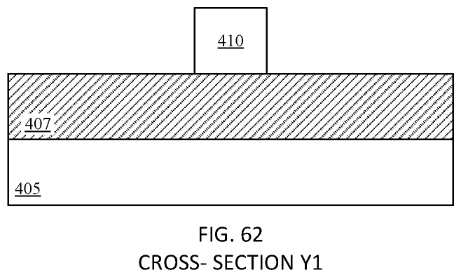

Referring now to FIGS. 62, a structure is shown during an intermediate step of a method of patterning the layers. FIG. 62 illustrates substrate 405, a first layer 407, and a channel layer 410. Substrate 405 can be, for example, a material including, but not necessarily limited to, silicon (Si), silicon germanium (SiGe), Si: C (carbon doped silicon), carbon doped silicon germanium (SiGe: C), III-V, II-V compound semiconductor or another like semiconductor. In addition, multiple layers of semiconductor materials can be used as the semiconductor material of substrate 305. In some embodiments, substrate 405 includes both semiconductor materials and dielectric materials. The semiconductor substrate 405 may also comprise an organic semiconductor or a layered semiconductor such as, for example, Si/SiGe, a silicon-on-insulator or a SiGe-on-insulator. A portion or the entire semiconductor substrate 405 may also be comprised of an amorphous, polycrystalline, or monocrystalline. Semiconductor substrate 405 may be doped, undoped or contain doped regions and undoped regions therein. The first layer 407 can be comprised of oxide material. Channel layer 410 can be comprised of, for example, Si or another suitable material. Channel layer 410 can be a nanosheet, nanowire, or another suitable structure. Channel layer 410 is formed/located directly on top of the first layer 407.

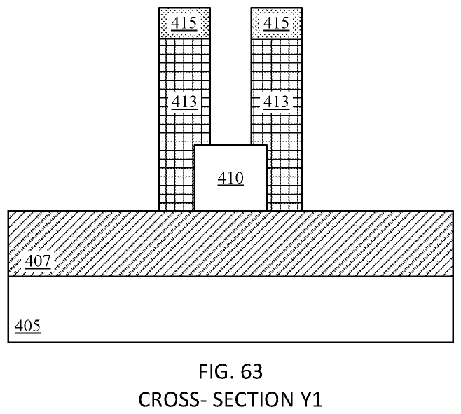

FIG. 63 illustrates the processing stage after formation and patterning of gate 413 and hardmask 415. Gate 413 is formed on top of the exposed surfaces of the first layer 407 and on top of the channel layer 410. Gate 413 can be comprised of, for example, a gate dielectric liner, such as high-k dielectric like HfO₂, ZrO₂, HfLₐOₓ, etc., and work function layers, such as TiN, TiAlC, TiC, etc., and conductive metal fills, like W, and low K dielectrics like SiO₂, Al₂O₃, or include non-work-function layers such as doped polySi etc.

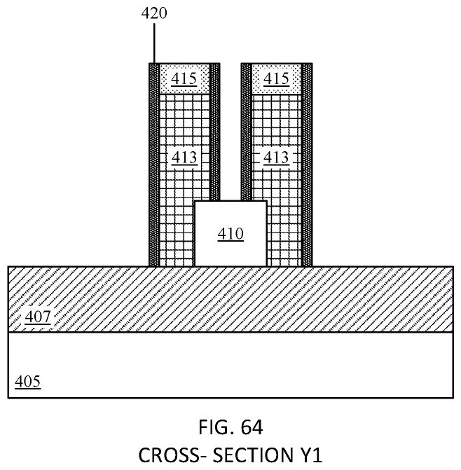

A hardmask 415 is formed on top of gate 413. Gate 413 and the hardmask 415 are patterned, such that, a column of the gate 413 and the hardmask 415 are located on opposite sides of the channel layer 410. Each column of gate 413 and the hardmask 415 extend along the length (i.e., in parallel) of channel layer 410. FIG. 64 illustrates the processing stage after gate spacers 420. Gate spacer layer is formed on the exposed surfaces and etched back to form gate spacers 420. Gate spacers 420 are located along the vertical sidewalls of each of the columns of the dummy gate 413 and the hardmask 415.

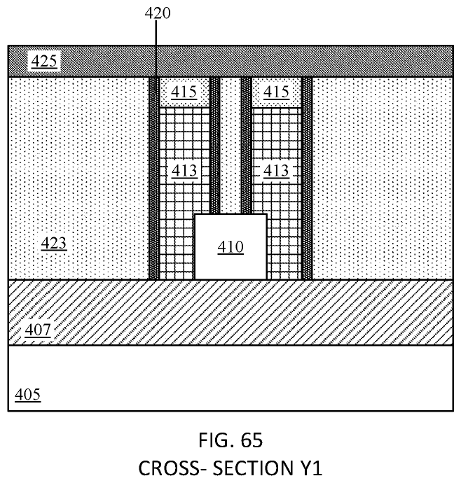

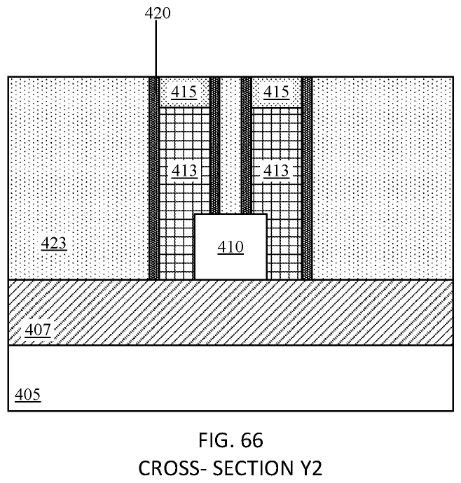

FIGS. 65 and 66 illustrate the processing stage after formation of an interlayer dielectric layer 423 and a lithography layer 425. An interlayer dielectric layer 423 is formed on top of the first layer 407 and the channel layer 410. The interlayer dielectric layer 423 is located adjacent to and in direct contact with gate spacers 420. The interlayer dielectric layer 423 is located on top of channel layer 410 between two vertical segments of gate spacers 420. Lithography layer 425 is formed on top of the interlayer dielectric layer 423, gate spacers 420, and hardmask 415. Lithography layer 425 is patterned to remove the layer in some locations, i.e., to create alternating columns of the where the lithography layer 425 is present and not present (i.e., sections where the lithography layer 425 was removed).

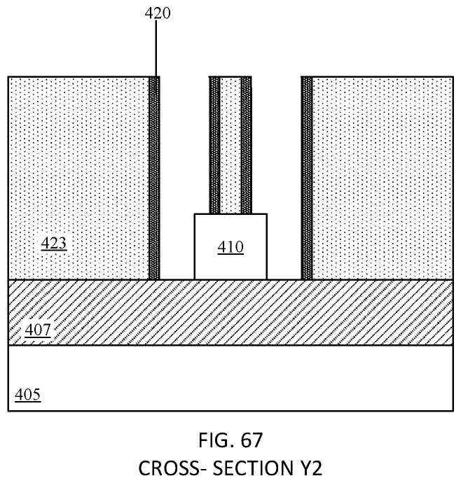

FIG. 67 illustrates the processing stage after removal of portions of the dummy gate 413 and hardmask 415. The portions of the dummy gate 413 and hardmask 415 are removed. The portions that are removed are the portions that were not protected/located underneath the lithograph layer. The removal of portions of gate 413 and hardmask 415 causes the solid column (comprised of the gate 413 and hardmask 415) to be divided into multiple sections.

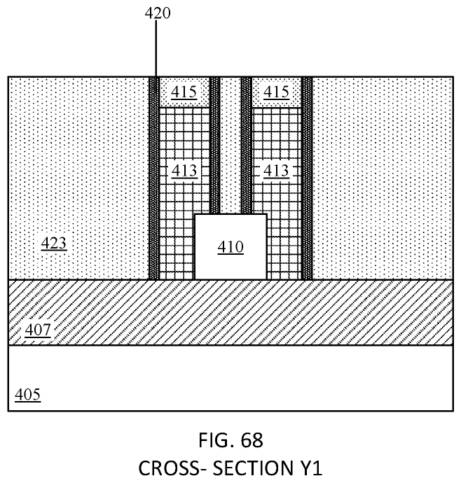

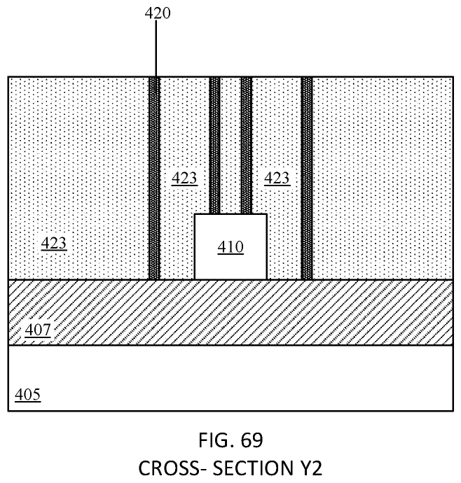

FIGS. 68 and 69 illustrate the processing stage after formation of additional interlayer dielectric layer 423 and removal of the lithograph layer 425. Additional interlayer dielectric material is added to fill the space (created by the removal of the gate 413 and the hardmask 415) between the vertical segments of gate spacer 420, as illustrated in FIG. 69. Lithography layer 425 is removed to create flat top surface/uniform surface along the quantum dot device.

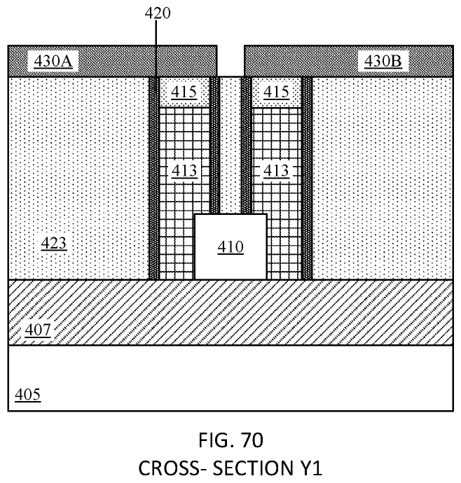

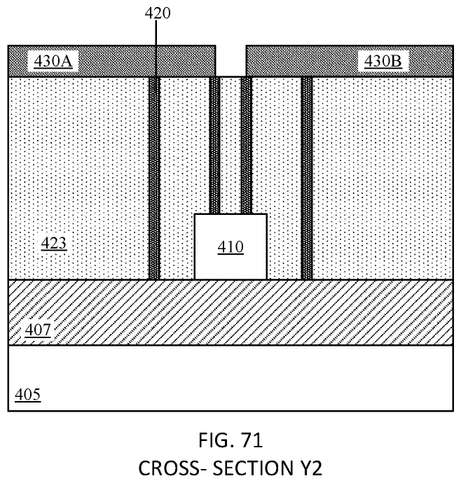

FIGS. 70 and 71 illustrate the processing stage after formation of section A 430A and section B 430B of the second lithography layer. A second lithography layer is formed on top of the interlayer dielectric layer 423, gate spacer 420, and hardmask 415. The second lithography layer is patterned to form Section A 430A and Section B 430B. The patterning of the second lithography layer forms an opening in the second lithography layer, where the opening is located above the center of channel layer 410. The opening exposes the top surface of a section of the interlayer dielectric layer 423 located between vertical sections of gate spacer 420, where the section of the interlayer dielectric layer 423 extends along the length and in parallel to the channel layer 410.

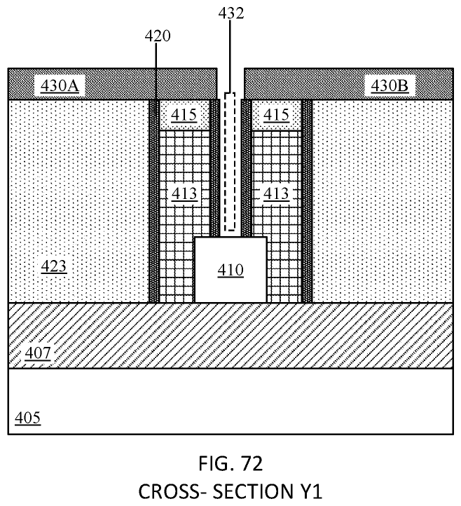

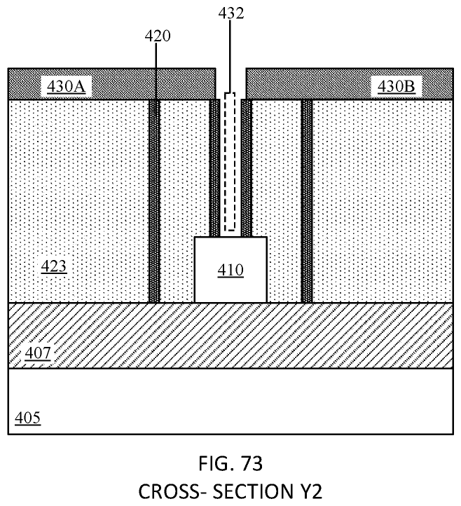

FIGS. 72 and 73 illustrate the processing stage after formation of a center gate trench 432. Center gate trench 432 is formed by removing the portion of the interlayer dielectric layer 423 exposed by Section A 430A and Section B of the second lithography layer. The center gate trench 432 is a trench that extends along the length of channel layer 410, where the side boundaries of the center gate trench 432 is formed by the gate spacer 420.

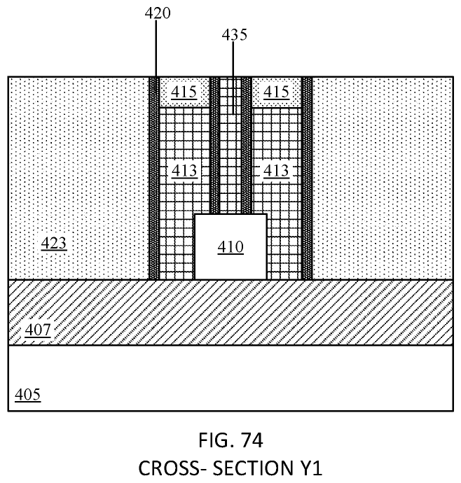

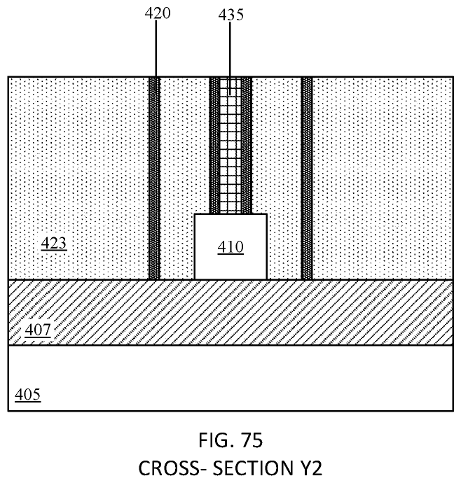

FIGS. 74 and 75 illustrate the processing stage after formation of a center gate 435. The center gate trench 432 is filled with a conductive metal to form the center gate 435. Center gate 435 is located directly on top of channel layer 410 and extends along the length of channel layer 410. Center gate 4435 can be comprised of, for example, a gate dielectric liner, such as high-k dielectric like HfO₂, ZrO₂, HfLₐOₓ, etc., and work function layers, such as TiN, TiAlC, TiC, etc., and conductive metal fills, like W, and low K dielectrics like SiO₂, Al₂O₃, or include non-work-function layers such as doped polySi etc.

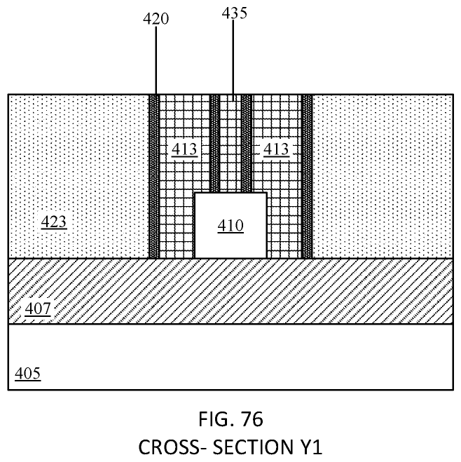

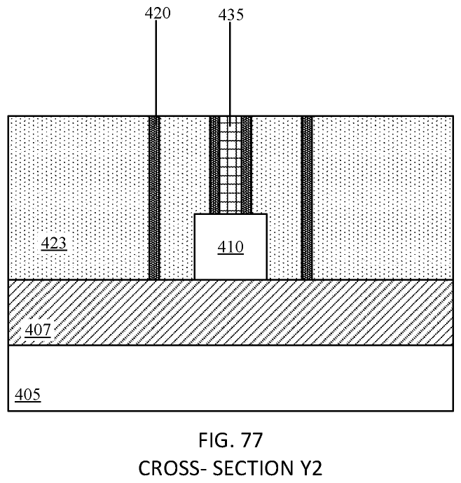

FIGS. 76 and 77 illustrate the processing stage after removal of excess material to expose a top surface of gates 413. The quantum dot device is subjected to a planarization process, such as, for example, chemical mechanical planarization (CMP) to expose a top surface of gates 413. Portions of the gate spacer 420 and the interlayer dielectric layer 423 are removed. The hardmask 415 is further removed during the planarization process.

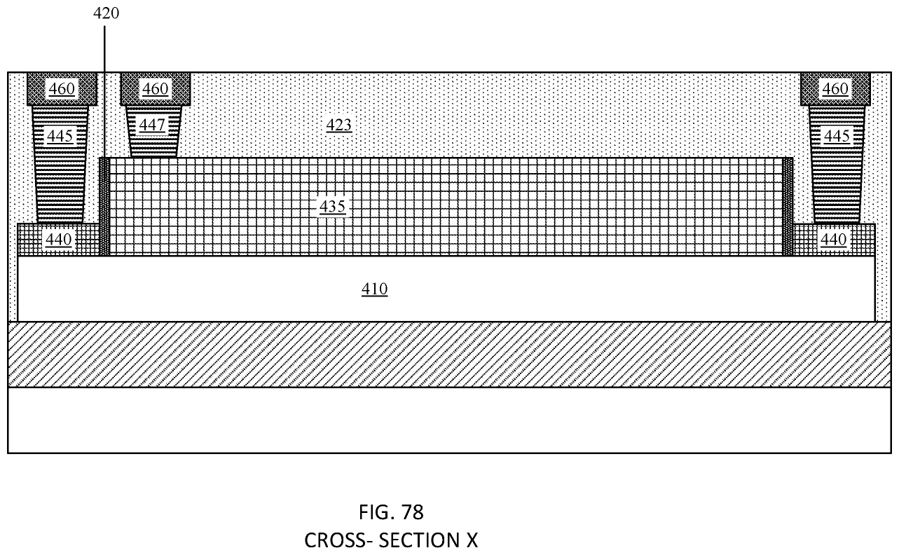

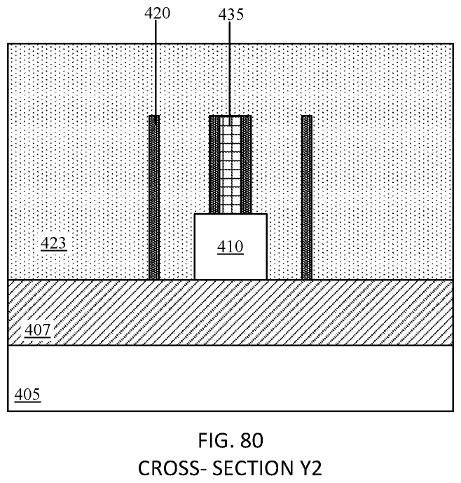

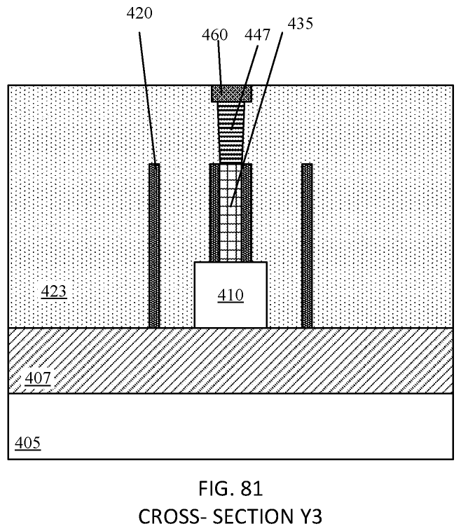

FIGS. 78, 79, 80 and 81 illustrate the processing stage after formation of source/drain contacts 445, high potential gate contacts (see FIG. 61), low potential gate contacts 450, formation of a center gate contact 447, formation of metal lines 460, and formation of quantum dots 470. Source/drains 440 were formed during a previous step, where the source/drains 440 are located in contact with channel layer 410. The source/drains 440 can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (TI) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

The height of the interlayer dielectric layer 423 is increased by adding more material, such that the interlayer dielectric layer 423 extends over the center gate 435, high potential gates (see, for example, FIG. 61), low potential gates 413L, and gate spacer 420. Trenches (not shown) are formed in the interlayer dielectric layer 423, to expose a top surface of the source/drains 440. The trenches are filled in with a conductive material to form the source/drain contacts 445. A trench (not shown) is formed in the interlayer dielectric layer 423 to expose a top surface of the center gate 435. The trench is filled with conductive material to form the center gate contact 447. A plurality of trenches (not shown) is formed in the interlayer dielectric layer 423, where each of the trenches exposes a top surface of the one of gates 413. These trenches are filled with conductive materials to form high potential gate contacts (see, for example, FIG. 61) and low potential gate contacts 450. The gates 413 connected to the high potential gate contacts will now be referred to as the high potential gates (see, for example, FIG. 61). The gates 413 connected to the low potential gate contacts 450 will now be referred to as the low potential gates 413L. The high potential gates and the low potential gates 413L are arranged in alternating fashion as illustrated in FIG. 61.

A back-end-of-the-line (BEOL) layer or metal connecting lines 460 is formed on top of the source/drain contacts 445, the center gate contact 447, the high potential gate contacts, the low potential gate contacts 450, and the second layer 423. A plurality of quantum dots 470 are formed along the channel layer 410. The quantum dots 470 can host spins which can be utilized for storing and manipulating quantum information. The quantum dots 470 are located along channel layer 410 in potential wells created by the low and high potential gates 413L. The adjacent high potential gates allow for controlling/tuning of the quantum dots 470. Furthermore, by having a high potential gate located on opposite sides of a low potential gate 413L (i.e., the low potential gate 413L is sandwiched between two adjacent high potential gates, see, for example, FIG. 61) increases the confinement of the quantum dots 470. A potential well (or low point) forms under the low potential gates 413L and the high point of the potential well (i.e. the upper raising walls/trend) is formed by the high potential gates. The quantum dots 470 are confined to the low point of the potential well, and by controlling the potential of the high potential gate allows for the controlling/tuning of the potential well and the quantum dot 470. The width of the high potential gate and the width of the low potential gate 413L also affect the confinement of the quantum dots 470. The center gate 435 is another high potential gate. Center gate 435 runs parallel to channel layer 410 and runs perpendicular to the high potential gates and the low potential gates 413L.

Quantum dots 470 are formed in a channel layer 410 by means of applying voltages to gate electrodes (high potential gates 413L, high potential gates) on top of the semiconductor, isolated by a dielectric (second layer 337). The voltages accumulate a small section in the channel layer 410, basically the quantum dot 470 is an isolated puddle of a single or a couple of charge carriers (positive or negative). To achieve this the present invention utilizes a four-gate confinement (high potential gate, low potential gate 413L, high potential gate) and the addition of the center gate 435. In the present invention, the direction of confinement is given by the nanowire (channel layer 410), additionally a four-gate system is needed plus at least one reservoir for charge carriers. The middle gate (e.g., the low potential gate 413L) defines the depth of the potential well and with the gates (e.g., the high potential gates) on the side can tune the coupling of the quantum dot 470 either to a neighboring/adjacent quantum dot 470 (or potential well) or the rate at which charge carriers can be loaded into your quantum dot 470. The center gate 435 allows for the tuning of the potential well, control the interaction between the two rails (the row of gates on each side of the center gate 435) and allows for magnetic driving of spin rotations of the spin qubits 470, i.e. single spin qubit control.

Therefore, the center gate 435 provides the opportunity to separate the two sides of the device and provides an additional means of tuning the quantum dots 470 located in the potential wells. Center gate 435 has the functionality of controlling the spins with a magnetic field arising from passing a current through that central gate 435.

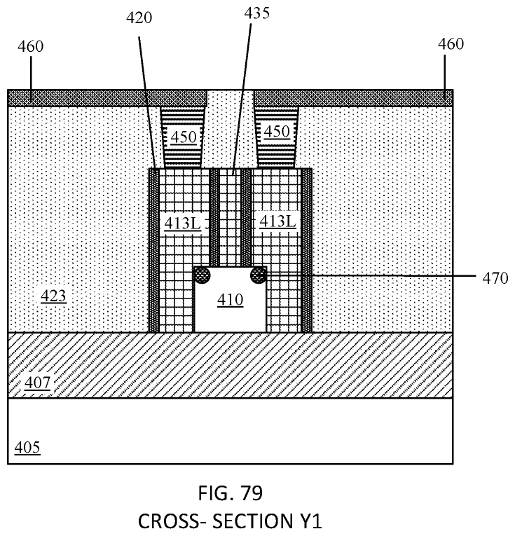

Center gate 435 provides another control/turning option for the potential well. As seen in FIGS. 61, and 79 cross-section Y1 illustrates a cut through the channel layer 410, a low potential gate 413L located on each side of the channel layer 310, and the center gate 435. Center gate 435 provides a high point potential well that will be formed between the two aligned low potential gates 413L. Therefore, center gate 435 provides the opportunity to form more quantum dots 470 on the channel layer 470 and provides an additional option for controlling/tuning the potential wells storing the quantum dots 470.

FIGS. 61, and 78-81 illustrate a four-gate formation (i.e., a low potential gate 413L sandwiched between two adjacent high potential gates, as illustrated in FIG. 61, and the center gate 435) for quantum dot 470 confinement. The first gate is a low potential gate 413L that is located adjacent to the nanosheet or nanowire (i.e., channel layer 410), see, for example, FIG. 79. The quantum dot 470 is located on the nanosheet (i.e., channel layer 410) beneath the low potential gate 413L. A second gate is located on the first side of the first gate and a third gate is located on the second side of the first gate. The gates are lined up along the length of the nanosheet (i.e., channel layer 410, see, for example, FIG. 61) in an alternating order, for example, the second gate (i.e., high potential gate), the first gate (i.e., the low potential gate 413L), then the third gate (i.e., another high potential gate). The fourth gate (i.e., the center gate 435) is located on top of the nanosheet or nanowire (i.e., channel layer 410). The fourth gate (i.e., the center gate 435) extends parallel to and along the length of the nanosheet/nanowire (i.e., channel layer 410). The fourth gate direction extends perpendicular to the first, second, and third gate direction, as illustrated in FIG. 61. The fourth gate or the center gate 435 is a high potential gate. The second gate, third gate, and the fourth gate allow for the control/tuning of the quantum dot 470.

A microelectronic structure (see, for example, FIGS. 1, 20, 36, 61) that includes a nanosheet or nanowire (110, 210, 310, 410). A first contact and a second contact (155, 255, 350, 445) connected to the nanosheet or nanowire (110, 210, 310, 410). A plurality of gates (133H, 133L, 233, 235, 325H, 325L, 413L, and high potential gates as indicated in FIG. 61) located between the first contact and the second contact (155, 255, 350, 445).

The plurality of gates (133H, 133L, 233, 235, 325H, 325L, 413L, and high potential gates as indicated in FIG. 61) is operated as a first low potential gate (133L, 235, 325L, 413L), a first high potential gate (133H, 233, 325H, and high potential gates as indicated in FIG. 61), and a second high potential gate (133H, 233, 325H, and high potential gates as indicated in FIG. 61).

The first low potential gate (133L, 235, 325L, 413L) is located between the first high potential gate and the second high potential gate (133H, 233, 325H, and high potential gates as indicated in FIG. 61) (see, for example, FIGS. 1, 20, 26, and 61).

A center gate (330, 435) located on top of the nanosheet or nanowire (310, 410). The center gate (330, 435) extends along the length of the nanosheet or nanowire (310, 410).

A center gate direction is perpendicular to a gate direction (see, for example, FIGS. 36 and 61) of the first and second high potential gate, and wherein the center gate direction is perpendicular to a gate direction of the first low potential gate direction (see, for example, FIGS. 36 and 61).

The plurality of gates includes a second low potential gate (325L, 413L), a third high potential gate (325H, and high potential gates as indicated in FIG. 61), and a fourth high potential gate (325H, and high potential gates as indicated in FIG. 61).

The first low potential gate (325L, 413L), the first high potential gate (325H, and high potential gates as indicated in FIG. 61), and the second high potential gate (325H, and high potential gates as indicated in FIG. 61) are located on a first side of the center gate (330, 425, see, for example, FIGS. 36, 61). The second low potential gate (325L, 413L), the third high potential gate (325H, and high potential gates as indicated in FIG. 61), and the fourth high potential gate (325H, and high potential gates as indicated in FIG. 61) are located on a second side of the center gate (330, 435, see, for example, FIGS. 36 and 61). The first side and second side of the center gate (330, 435) are opposite of each other (see, for example, FIGS. 36 and 61).

A microelectronic structure (see, for example, 36, and 61) that includes a nanosheet or nanowire (310, 410). A first contact and a second contact (350, 445) connected to the nanosheet or nanowire (310, 410). A plurality of gates (325H, 325L, 413L, and high potential gates as indicated in FIG. 61) located between the first contact and the second contact (350, 445). A center gate (330, 435) located directly on top of the nanosheet or nanowire (310, 410).

The plurality of gates (325H, 325L, 413L, and high potential gates as indicated in FIG. 61) includes a first low potential gate (325L, 413L), a first high potential gate (325H, and high potential gates as indicated in FIG. 61), and a second high potential gate (325H, and high potential gates as indicated in FIG. 61).

The first low potential gate (315L, 413L) is located between the first high potential gate (325H, and high potential gates as indicated in FIG. 61) and the second high potential gate (325H, and high potential gates as indicated in FIG. 61).

The center gate (330, 435) extends along a length of the nanosheet or nanowire (310, 410).

A center gate direction is perpendicular to a gate direction (see, for example, FIGS. 36 and 61) of the first and second high potential gate, and wherein the center gate direction is perpendicular to a gate direction of the first low potential gate direction (see, for example, FIGS. 36 and 61).

The plurality of gates includes a second low potential gate (325L, 413L), a third high potential gate (325H, and high potential gates as indicated in FIG. 61), and a fourth high potential gate (325H, and high potential gates as indicated in FIG. 61).

The first low potential gate (325L, 413L), the first high potential gate (325H, and high potential gates as indicated in FIG. 61), and the second high potential gate (325H, and high potential gates as indicated in FIG. 61) are located on a first side of the center gate (330, 425, see, for example, FIGS. 36, 61). The second low potential gate (325L, 413L), the third high potential gate (325H, and high potential gates as indicated in FIG. 61), and the fourth high potential gate (325H, and high potential gates as indicated in FIG. 61) are located on a second side of the center gate (330, 435, see, for example, FIGS. 36 and 61). The first side and second side of the center gate (330, 435) are opposite of each other (see, for example, FIGS. 36 and 61).

The center gate (330, 435) is a high potential gate.

A method of operation that includes a nano quantum dot device. The nano quantum dot device that includes a nanosheet or nanowire (110, 210, 310, 410). A first contact and a second contact (155, 255, 350, 445) connected to the nanosheet or nanowire (110, 210, 310, 410). A plurality of gates (133H, 133L, 233, 235, 325H, 325L, 413L, and high potential gates as indicated in FIG. 61) located between the first contact and the second contact (155, 255, 350, 445). At least a three-gate group is formed from the plurality of gates (133H, 133L, 233, 235, 325H, 325L, 413L, and high potential gates as indicated in FIG. 61). The three-gate group have a set alignment order for the potential of each of the gates (133H, 133L, 233, 235, 325H, 325L, 413L, and high potential gates as indicated in FIG. 61) in the three-gate group and the alignment order consists of a first high potential gate (133H, 233, 325H, and high potential gates as indicated in FIG. 61), a low potential gate (133L, 235, 325L, 413L) and a second high potential gate (133H, 233, 325H, and high potential gates as indicated in FIG. 61).

The operation of the three-gate group (133H, 133L, 233, 235, 325H, 325L, 413L, and high potential gates as indicated in FIG. 61) causes a potential well to be formed under the low potential gate (133L, 235, 325L, 413L). A quantum dot (160, 260, 360, 470) that can host a spin is formed in the potential well.

The nano quantum dot device further includes a center gate (330, 435) located directly on top of the nanosheet or nanowire (310, 410). The center gate (330, 435) extends the length of the nanosheet or nano wire (310, 410). The center gate (330, 435) is arranged perpendicular to the plurality of gates (325H, 325L, 413L, and high potential gates as indicated in FIG. 61). A four-gate group is created from the center gate (330, 435) and the three-gate group (325H, 325L, 413L, and high potential gates as indicated in FIG. 61). The center gate (330, 435) controls the spin of the quantum dot (360, 470) contained within the potential well.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A microelectronic structure comprising:
a nanosheet or nanowire;
a first contact and a second contact connected to the nanosheet or nanowire; and
a plurality of gates located between the first contact and the second contact.

2. The microelectronic structure of claim 1, wherein the plurality of gates is operated as a first low potential gate, a first high potential gate, and a second high potential gate.

3. The microelectronic structure of claim 2, wherein the first low potential gate is located between the first high potential gate and the second high potential gate.

4. The microelectronic structure of claim 3, further comprising:
a center gate located on top of the nanosheet or nanowire, wherein the center gate extends along the length of the nanosheet or nanowire.

5. The microelectronic structure of claim 4, wherein a center gate direction is perpendicular to a gate direction of the first and second high potential gate, and wherein the center gate direction is perpendicular to a gate direction of the first low potential gate.

6. The microelectronic structure of claim 5, wherein the plurality of gates includes a second low potential gate, a third high potential gate, and a fourth high potential gate.

7. The microelectronic structure of claim 6, wherein the first low potential gate, the first high potential gate, and the second high potential gate are located on a first side of the center gate, and wherein the second low potential gate, the third high potential gate, and the fourth high potential gate are located on a second side of the center gate, wherein the first side and second side of the center gate are opposite of each other.

8. A microelectronic structure comprising:
a nanosheet or nanowire;
a first contact and a second contact connected to the nanosheet or nanowire;
a plurality of gates located between the first contact and the second contact along the side of the nanosheet or nanowire; and
a center gate located directly on top of the nanosheet or nanowire.

9. The microelectronic structure of claim 8, wherein the plurality of gates includes a first low potential gate, a first high potential gate, and a second high potential gate.

10. The microelectronic structure of claim 9, wherein the first low potential gate is located between the first high potential gate and the second high potential gate.

11. The microelectronic structure of claim 10, wherein the center gate extends along a length of the nanosheet or nanowire.

12. The microelectronic structure of claim 11, wherein a center gate direction is perpendicular to a gate direction of the first and second high potential gate, and wherein the center gate direction is perpendicular to a gate direction of the first low potential gate.

13. The microelectronic structure of claim 12, wherein the plurality of gates includes a second low potential gate, a third high potential gate, and a fourth high potential gate.

14. The microelectronic structure of claim 13, wherein the first low potential gate, the first high potential gate, and the second high potential gate are located on a first side of the center gate, and wherein the second low potential gate, the third high potential gate, and the fourth high potential gate are located on a second side of the center gate, wherein the first side and second side of the center gate are opposite of each other.

15. The microelectronic structure of claim 14, wherein the center gate is a high potential gate.

16. The microelectronic structure of claim 8, wherein the center gate is a high potential gate.

17. A method of operation comprising:
a nano quantum dot device that includes:
a nanosheet or nanowire;
a first contact and a second contact connected to the nanosheet or nanowire; and
a plurality of gates located between the first contact and the second contact;
at least a three-gate group is formed from the plurality of gates, wherein the three-gate group has a set alignment order for the potential of each of the gates in the three-gate group, wherein the alignment order consists of a first high potential gate, a low potential gate, and a second high potential gate.

18. The method of operation of claim 17, wherein the operation of the three-gate group causes a potential well to be formed under the low potential gate, wherein a quantum dot that can host a spin is formed in the potential well.

19. The method of operation of claim 18, wherein the nano quantum dot device further comprises:
a center gate located directly on top of the nanosheet or nanowire, wherein the center gate extends the length of the nanosheet or nano wire, wherein the center gate is arranged perpendicular to the plurality of gates.

20. The method of operation of claim 19, wherein a four-gate group is created from the center gate and the three-gate group, wherein the center gate controls the spin of the quantum dot contained within the potential well.
